(19) United States
(12) Patent Application Publication
(10) Pub. No.: US 2024/0355654 A1
(43) Pub. Date: Oct. 24, 2024

(54) SUBSTRATE PROCESSING SYSTEM

(71) Applicant: Brooks Automation US, LLC, Chelmsford, MA (US)

(72) Inventors: Jairo T. Moura, Marlborough, MA (US); Robert T. Caveney, Windham, NH (US)

(21) Appl. No.: 18/758,976

(22) Filed: Jun. 28, 2024

Related U.S. Application Data
(60) Provisional application No. 63/479,431, filed on Jan. 11, 2023.

(30) Foreign Application Priority Data
Jan. 9, 2024 (WO) PCT/US2024/010885

(51) Int. Cl. H01L 21/67; G05B 19/418

(52) U.S. Cl. CPC H01L 21/67276; G05B 19/4183; G05B 19/4189; H01L 21/67196; G05B 2219/37388; G05B 2219/37536

(57) ABSTRACT

A substrate processing system comprising, a frame forming a substrate transport space within the substrate processing system, a substrate transport apparatus operably coupled to the frame with a movable arm and a drive section configured to move the movable arm and transport a substrate, held on an end effector of the arm, through the transport space from a first position of the substrate processing system to a second position of the substrate processing system different than the first position; and a controller operably coupled to the movable arm and drive section so as to effect movement of the movable arm to the different system positions, the controller is communicably coupled to at least one arm motion sensor and at least one system metrology sensor, and the at least one system metrology sensor senses system metrology predetermined characteristics, different that the arm motion predetermined characteristics.

### CROSS-REFERENCE TO RELATED APPLICATIONS

This application is the National Stage of International Application Number PCT/US2024/010885 having an International Filing Date of 9 Jan. 2024, which designated the United States of America, which claims priority from, and the benefit of U.S. provisional patent application No. 63/479,431 filed Jan. 11, 2023, the disclosure of which is incorporated herein by reference it its entirety.

### BACKGROUND

### 1. Field

The exemplary embodiments generally relate to automated processing systems, and more particularly, to automated processing system diagnostics.

### 2. Brief Description of Related Developments

Automated processing systems such as semiconductor processing systems include multiple components that support the implementation of processes that effect predetermined levels of quality and reproducibility in semiconductor chip manufacturing. Examples of the multiple components include wafer handlers (e.g., robotic manipulators), wafer handler motion controllers, wafer presence sensors, slot valves, load locks, process modules, transfer modules, tool safety controllers, and tool host controllers. Typically these multiple components are employed in an automated processing system as separate modules and operate in a respective domain, where the tool host controller (and sometimes the wafer handler controller) is in communication with one or more other components of the multiple components for sending commands for wafer transport and/or processing.

### BRIEF DESCRIPTION OF THE DRAWINGS

The foregoing aspects and other features of the disclosed embodiment are explained in the following description, taken in connection with the accompanying drawings, wherein:

FIG. 1A is a schematic perspective illustration of an exemplary substrate processing system incorporating aspects of the disclosed embodiment;

FIG. 1B is a schematic plan illustration of the substrate processing system of FIG. 1A in accordance with aspects of the disclosed embodiment;

FIG. 1C is a schematic plan illustration of an exemplary substrate processing system incorporating aspects of the disclosed embodiment;

FIG. 1D is a schematic elevation illustration of an exemplary substrate processing system incorporating aspects of the disclosed embodiment;

FIGS. 2A-2D are schematic plan illustrations of exemplary substrate processing systems incorporating aspects of the disclosed embodiment;

FIGS. 2E-2I are schematic perspective illustrations of exemplary substrate transport apparatus incorporating aspects of the disclosed embodiment;

FIG. 3 is a schematic illustration of a portion of a modular metrology station in accordance with aspects of the disclosed embodiment;

FIG. 4 is a schematic illustration of a portion of a modular metrology station in accordance with aspects of the disclosed embodiment;

FIG. 5 is a schematic illustration of exemplary substrate processing system, that is generic to the substrate processing systems and components thereof shown in FIGS. 1A-2I, incorporating aspects of the disclosed embodiment;

FIG. 6 is a schematic plan illustration of a portion of the substrate processing system of FIG. 5 in accordance with aspects of the disclosed embodiment;

FIG. 7 is a schematic plan illustration of a portion of the substrate processing system of FIG. 5 in accordance with aspects of the disclosed embodiment;

FIG. 8 is a schematic illustration of a portion of the substrate processing system of FIG. 5 in accordance with aspects of the disclosed embodiment;

FIG. 9 is a schematic illustration of a portion of the substrate processing system of FIG. 5 in accordance with aspects of the disclosed embodiment;

FIG. 10 is an exemplary flow diagram illustrating an adaptation control law for maximizing a system level characteristic of the substrate processing apparatus of FIG. 5 based on control variables of the substrate processing apparatus in accordance with aspects of the disclosed embodiment;

FIG. 11 is an exemplary flow diagram of an adaptation control law for minimizing a system level characteristic of the substrate processing apparatus of FIG. 5 based on control variables of the substrate processing apparatus in accordance with aspects of the disclosed embodiment;

FIG. 12 is an exemplary graph illustrating an adaptation of predetermined functional characteristic indices and their respective variables to effect maximization of one or more of the predetermined functional characteristic indices of the substrate processing apparatus of FIG. 5 in accordance with aspects of the disclosed embodiment;

FIG. 13 is an exemplary flow diagram of a method in accordance with the aspects of the disclosed embodiment; and

FIG. 14 is an exemplary flow diagram of a method in accordance with the aspects of the disclosed embodiment.

### DETAILED DESCRIPTION

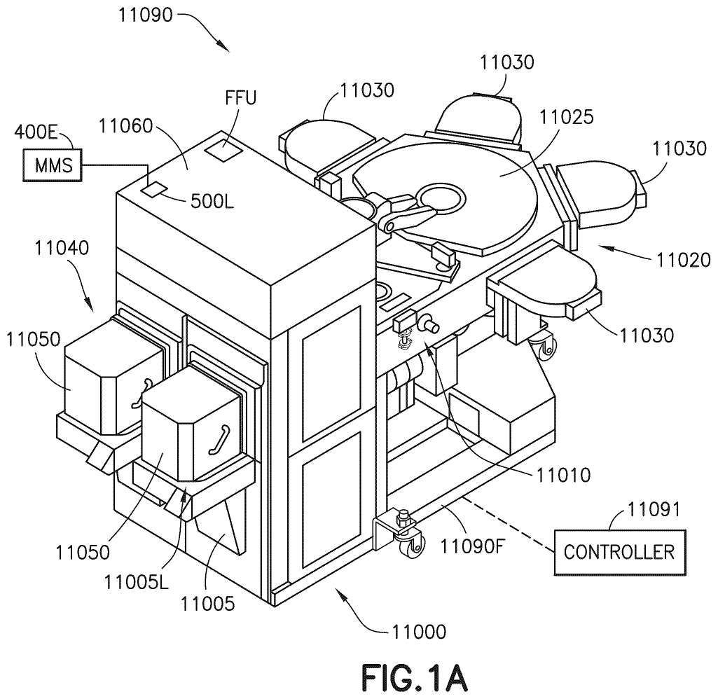

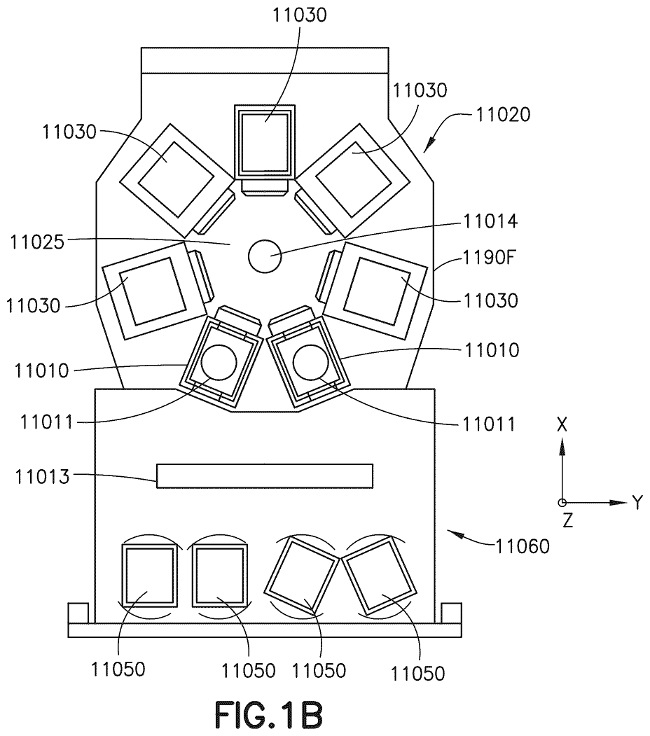

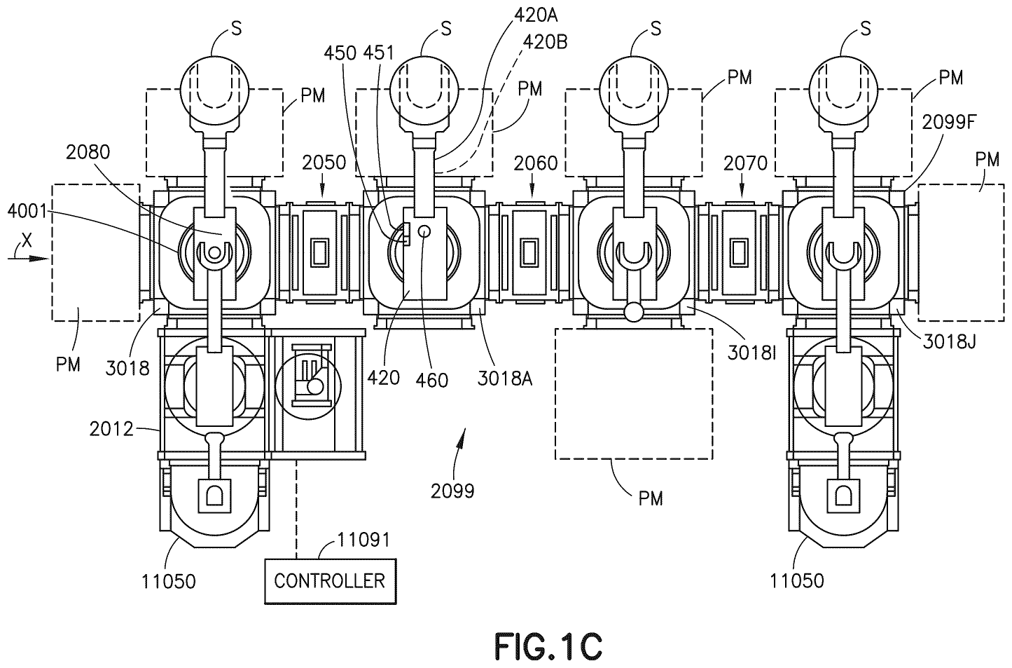

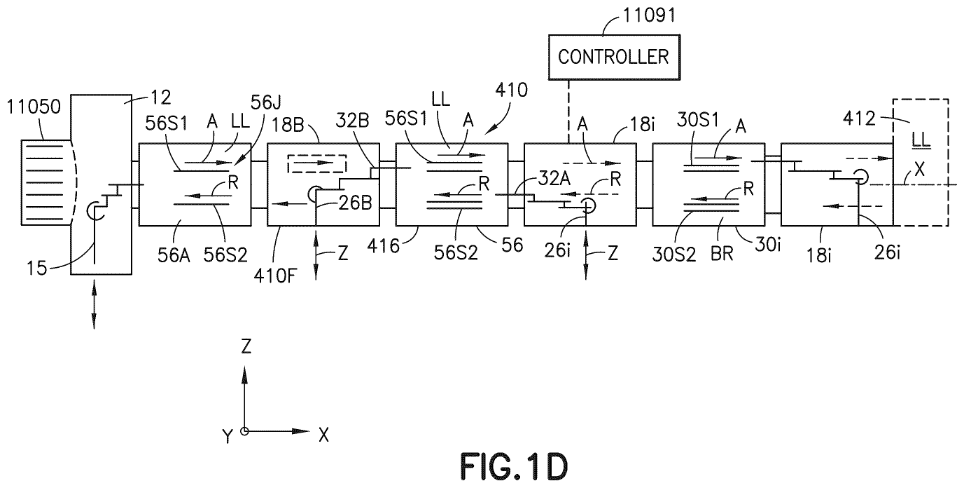

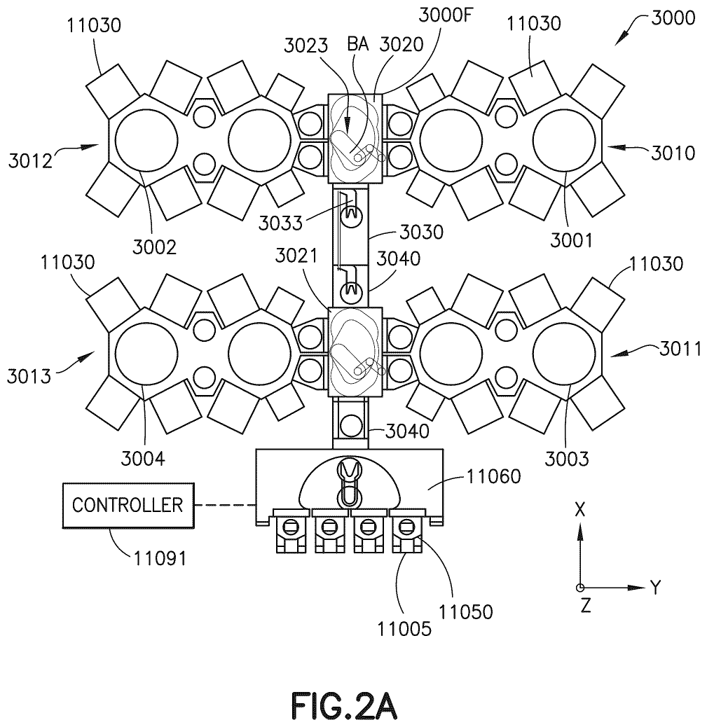

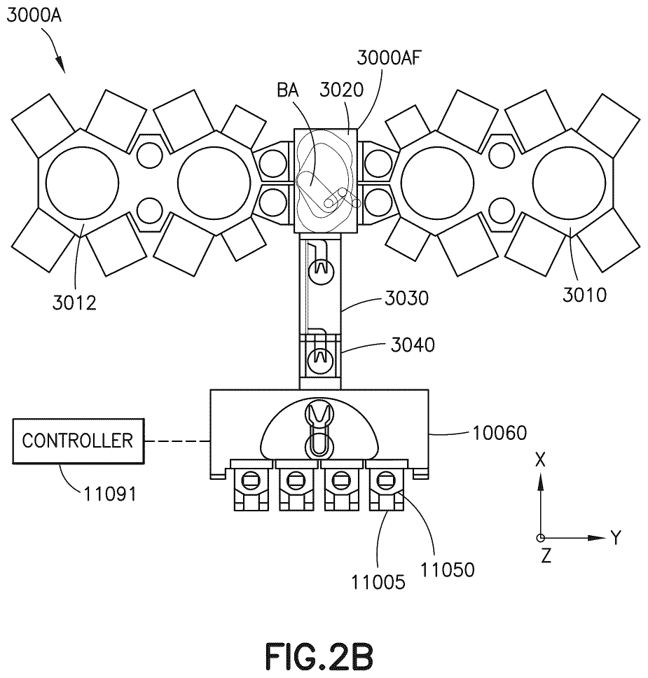

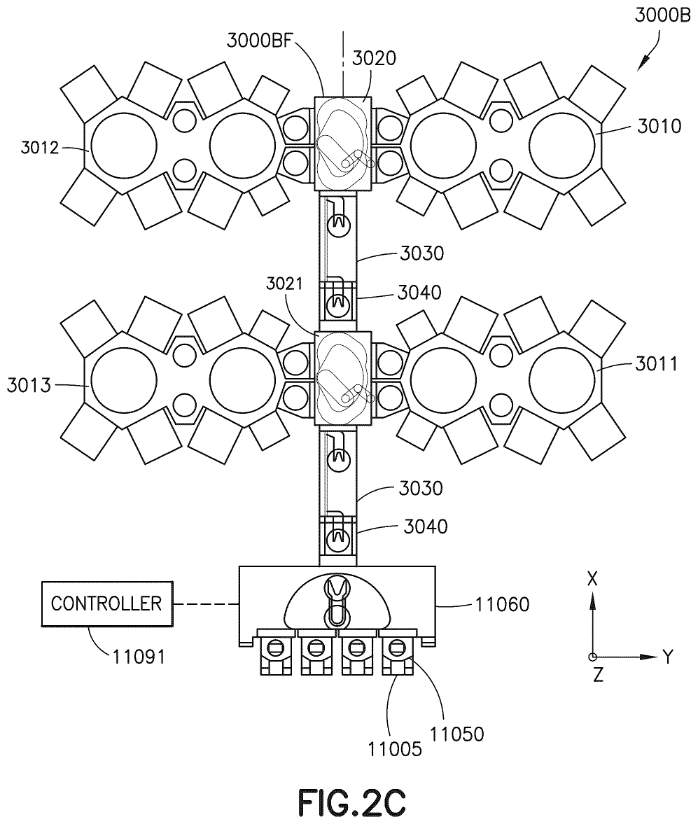

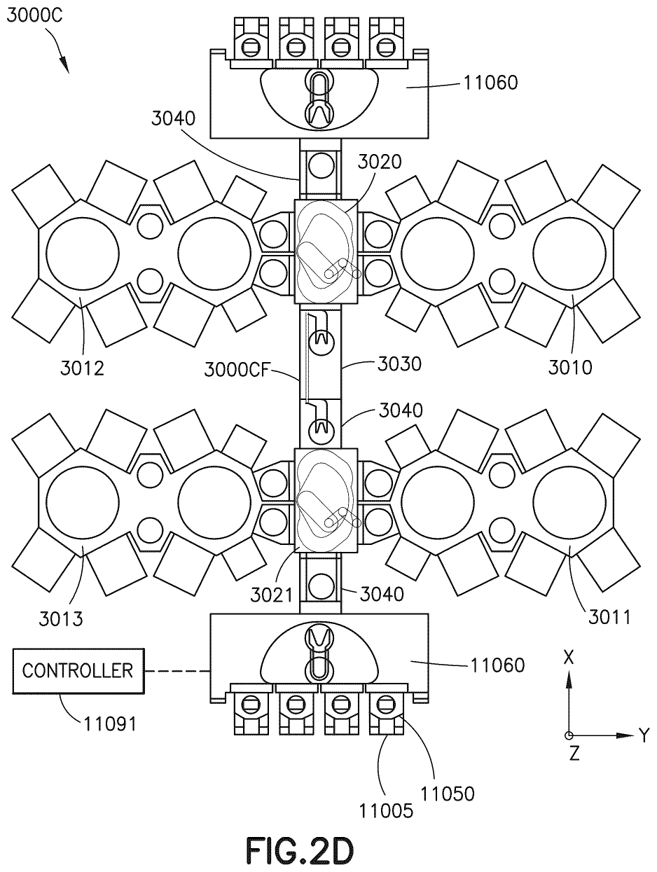

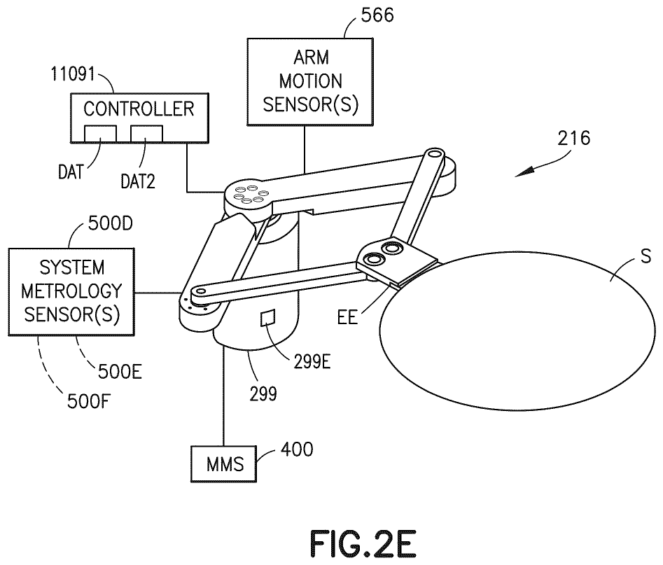

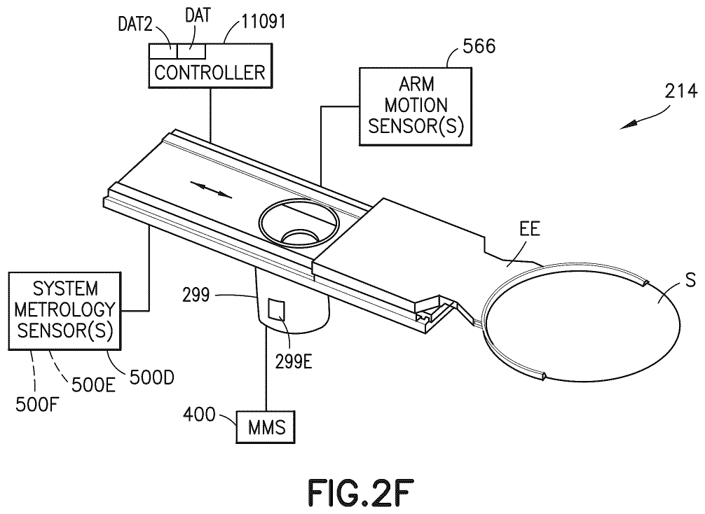

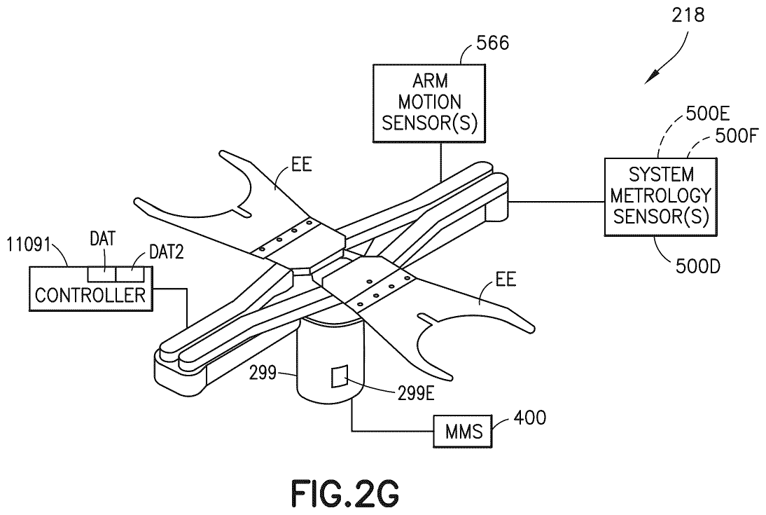

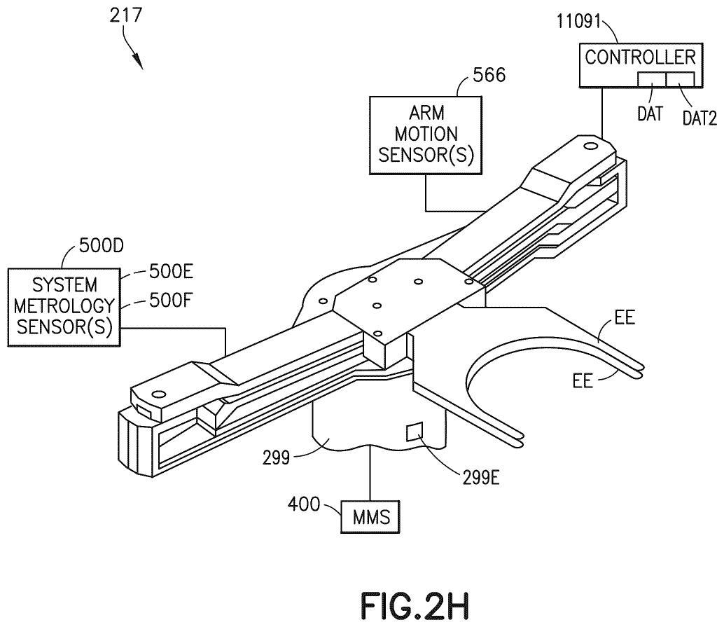

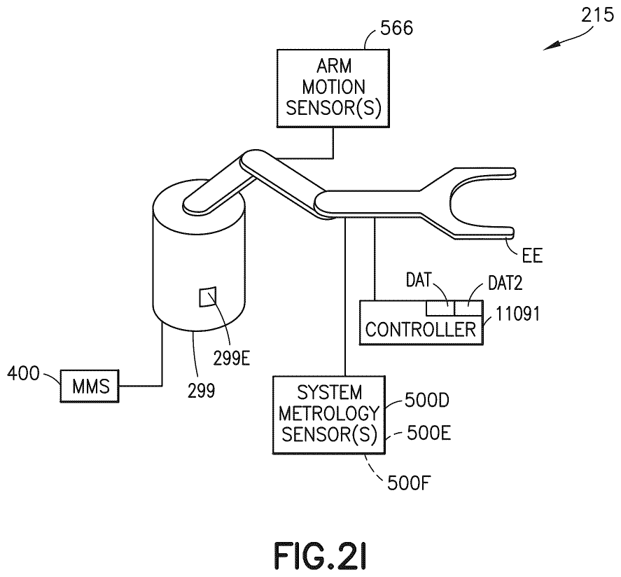

FIGS. 1-2D illustrate exemplary substrate processing systems 410, 11090, 2099, 3000, 3000A, 3000B, 3000C in accordance with aspects of the disclosed embodiment. Although the aspects of the disclosed embodiment will be described with reference to the drawings, it should be understood that the aspects of the disclosed embodiment can be embodied in many forms. In addition, any suitable size, shape or type of elements or materials could be used.

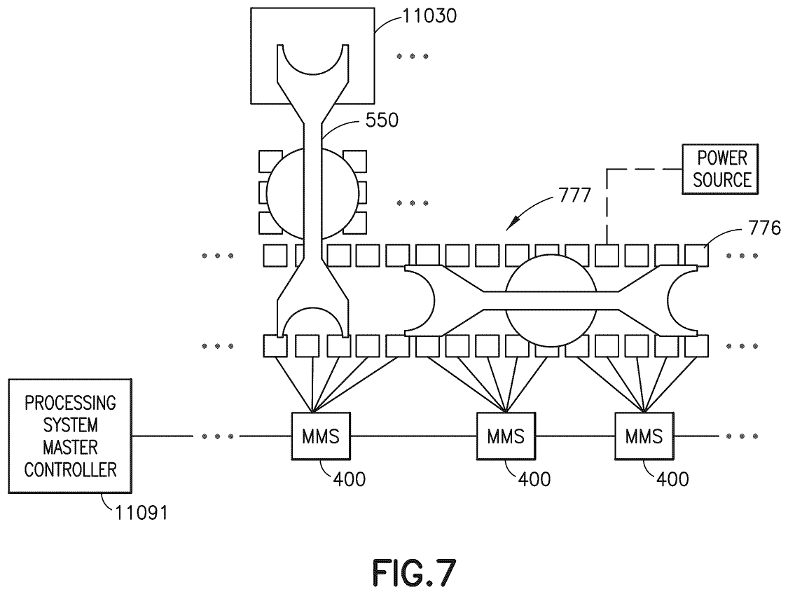

Each of the substrate processing systems 410, 11090, 2099, 3000, 3000A, 3000B, 3000C has a frame 410F, 1190F, 2099F, 3000F, 3000AF, 3000BF, 3000CF that forms a substrate transport space within the respective substrate processing system 410, 11090, 2099, 3000, 3000A, 3000B, 3000C. A substrate transport apparatus or wafer or substrate handler 11013, 11014, 2080, 26B, 26i, 3023, 3033, 550 is operably coupled to the frame 410F, 1190F, 2099F, 3000F, 3000AF, 3000BF, 3000CF. The substrate transport apparatus 11013, 11014, 2080, 26B, 26i, 3023, 3033, 550 has a movable articulated arm 214-218 (referred to herein as an arm) and drive section 299 configured to move the arm 214-218 and transport a wafer or substrate S (the terms wafer and substrate are used interchangeably herein but it is noted that the substrate may be any suitable workpiece), held on an end effector EE of the arm 214-218, through the transport space from a first position (e.g., any of the substrate holding locations described herein) of the substrate processing system 410, 11090, 2099, 3000, 3000A, 3000B, 3000C to a second position (e.g., any of the substrate holding locations described herein) of the substrate processing system 410, 11090, 2099, 3000, 3000A, 3000B, 3000C different than the first position. The arm drive section may be a rotary drive section having one or more drive shafts driven by a suitable motor (see FIGS. 2E-2I) or a linear drive section 777 (FIG. 7) having distributed electromagnetic drive elements 776 that magnetically levitate and drive motion the arm 550A. A suitable example of a linear drive section and transport system in which the aspects of the disclosed embodiment may be employed is described in U.S. patent application Ser. No. 17/180,298 filed on Feb. 19, 2021 and titled “Substrate Process Apparatus,” the disclosure of which is incorporated herein by reference in its entirety.

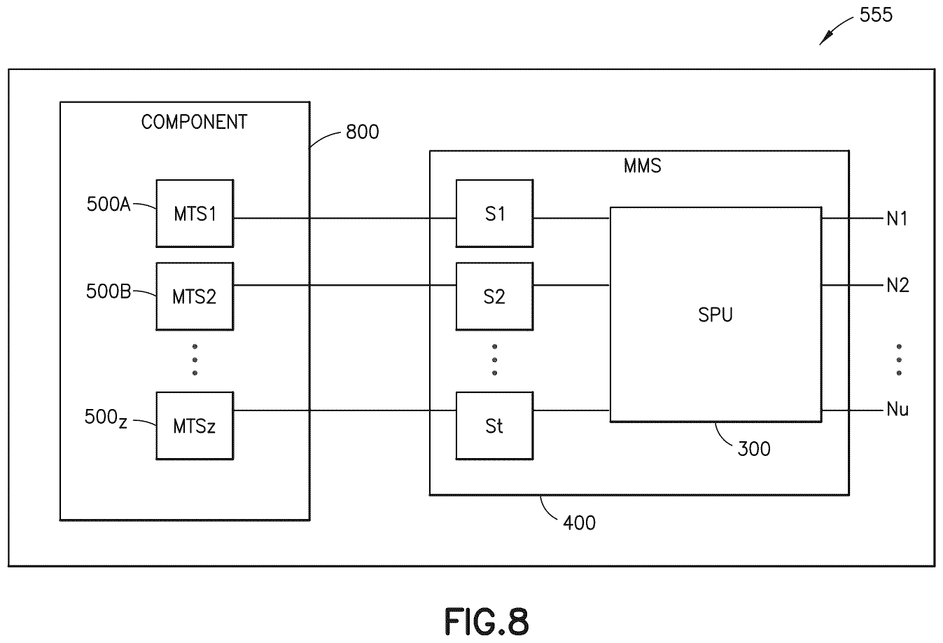

The substrate processing systems 410, 11090, 2099, 3000, 3000A, 3000B, 3000C are configured with a respective sensing system that effects an intelligent symbiotic and adaptive relationship between at least wafer handler controls and various other components of the substrate processing systems 410, 11090, 2099, 3000, 3000A, 3000B, 3000C. Unlike with the conventional automated processing systems described above, the aspects of the disclosed embodiment provide for the sharing of information between respective domains of the various components 800 (as described herein, see FIG. 8) of the substrate processing systems 410, 11090, 2099, 3000, 3000A, 3000B, 3000C. For example, substrate transport apparatus 11013, 11014, 2080, 26B, 26i, 3023, 3033, 550 operating in substrate processing system 410, 11090, 2099, 3000, 3000A, 3000B, 3000C is controlled based on sensor feedback that embodies at least operating characteristics (e.g., vibrations, temperature, air flow, etc.—as described herein) of other components (e.g., slot valves, other substrate transport apparatus, process modules, aligners, front end units, etc.—as described herein) of the substrate processing systems 410, 11090, 2099, 3000, 3000A, 3000B, 3000C. The controlled movements of the substrate transport apparatus may be modified/adapted depending on the operating characteristics of the other components. The intelligent symbiotic and adaptive relationship between at least the wafer handler controls and various other components of the substrate processing systems 410, 11090, 2099, 3000, 3000A, 3000B, 3000C may provide an increased value and reduction of cost of ownership of the substrate processing systems 410, 11090, 2099, 3000, 3000A, 3000B, 3000C by improving productivity metrics, such as wafers processed per hour (WPH), increased tool uptime (e.g., time the processing system is operational), reduced service times, reduced preventative maintenance occurrences, and reduced setup times.

As will be described herein, the aspects of the disclosed embodiment define substrate processing tool variables and associated performance indices that are employed in support of an adaptive controls and diagnostics framework that modify system level performance attributes to maximize the productivity metrics, such as wafers processed per hour (WPH), increased tool uptime (e.g., time the processing system is operational), reduced service times, reduced preventative maintenance occurrences, and reduced setup times.

Referring to FIGS. 1A and 1B, a processing apparatus, such as for example a semiconductor processing system 11090 is shown in accordance with aspects of the disclosed embodiment. Although a semiconductor processing system 11090 is shown in the drawings, the aspects of the disclosed embodiment described herein can be applied to any tool station or application employing robotic manipulators. In this example the semiconductor processing system 11090 is shown as a cluster tool, however the aspects of the disclosed embodiment may be applied to any suitable tool station such as, for example, a linear tool station such as that shown in FIGS. 1C and 1D and described in U.S. Pat. No. 8,398,355, entitled “Linearly Distributed Semiconductor Workpiece Processing Tool,” issued Mar. 19, 2013 and a linear tool station as described in U.S. patent application Ser. No. 17/180,298, titled “Substrate Processing Apparatus” and filed on Feb. 19, 2021, the disclosures of which are incorporated by reference herein in their entireties. The semiconductor tool station or processing system 11090 generally includes an atmospheric front end 11000, a vacuum load lock 11010 and a vacuum back end 11020. In other aspects, the tool station may have any suitable configuration. The components of each of the front end 11000, vacuum load lock 11010 and vacuum back end 11020 may be connected to a controller 11091 which may be part of any suitable control architecture such as, for example, a clustered architecture control.

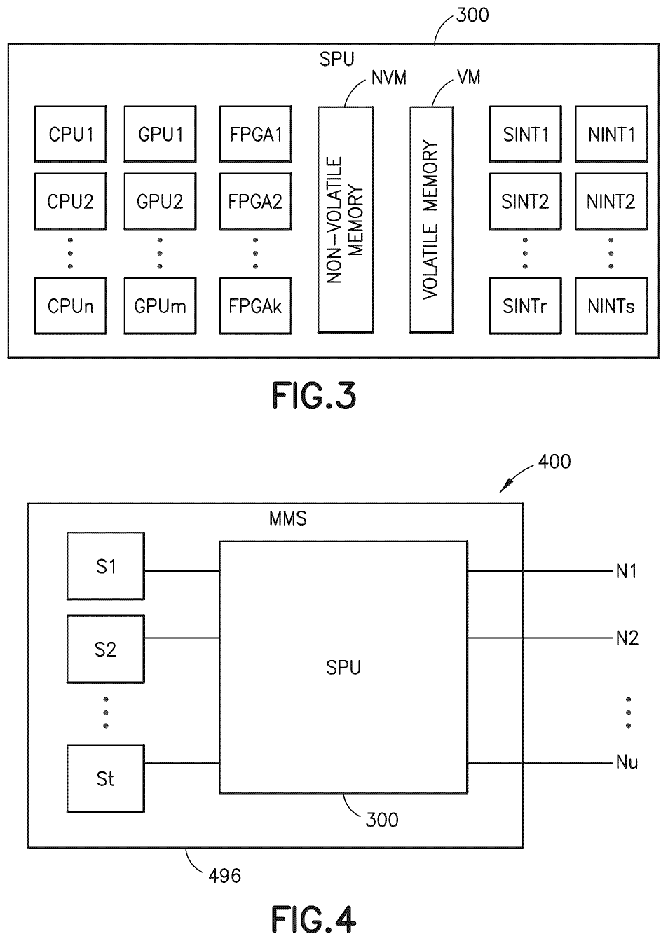

The controller 11091 may be a closed loop controller having a master controller, cluster controllers and autonomous remote controllers such as those disclosed in U.S. Pat. No. 7,904,182 entitled “Scalable Motion Control System” issued on Mar. 8, 2011 the disclosure of which is incorporated herein by reference in its entirety. In other aspects, any suitable controller and/or control system may be utilized. As will be described herein, the controller 11091 is communicably connected to a drive section (e.g., such as drive section 299—see FIGS. 2E-2F) of a substrate transport robot (such as those described herein and also referred to as a substrate transport apparatus or handler) to move the transport arm (such as transport arms 214-218 in FIGS. 2E-2I—or any of the other transport arms described herein). The controller 11091 is also communicably connected to the at least one sensor processing unit 300 (see FIG. 3) described herein to effect the intelligent symbiotic and adaptive relationship between the components of the semiconductor processing system 11090.

In one aspect, the front end 11000 generally includes load port modules (also referred to herein as a workpiece load station) 11005 and a mini-environment 11060 such as for example an equipment front end module (EFEM) (which in some aspects includes a wafer sorting function). In other aspects the processing stations include wafer buffers, wafer inverters and wafer shuffle stations (which may be located in the vacuum back end 11020, in the front end 11000 and/or connecting the front end 11000 with vacuum the vacuum back end 11020 (e.g. such as in a load lock). The front end 11000 and vacuum back end 11020 each include a frame which when coupled to each other form a frame 11090F of the semiconductor processing system 11090. The load port modules 11005 may be box opener/loader to tool standard (BOLTS) interfaces that conform to SEMI standards E15.1, E47.1, E62, E19.5 or E1.9 for 300 mm load ports, front opening or bottom opening boxes/pods and cassettes. In other aspects, the load port modules may be configured as 200 mm wafer or 450 mm wafer interfaces or any other suitable wafer interfaces such as for example larger or smaller wafers or flat panels for flat panel displays. Although two load port modules 11005 are shown in FIG. 1A, in other aspects any suitable number of load port modules may be incorporated into the front end 11000. The load port modules 11005 may be configured to receive wafer/substrate carriers or cassettes 11050 from an overhead transport system, automatic guided vehicles, person guided vehicles, rail guided vehicles or from any other suitable transport method. The load port modules 11005 may interface with the mini-environment 11060 through load ports 11040. The substrate cassettes 11050 are received on a respective load port module 11005 at a predetermined load station reference location 11005L that kinematically locates the substrate cassettes 11050 on the load port module 11005. In one aspect the load ports 11040 allow the passage of wafers between the substrate cassettes 11050 and the mini-environment 11060.

In one aspect, the mini-environment 11060 generally includes any suitable transport robot 11013. In one aspect the transport robot 11013 may be a track mounted robot such as that described in, for example, U.S. Pat. Nos. 6,002,840 and 7,066,707, the disclosures of which are incorporated by reference herein in their entireties or in other aspects, any other suitable transport robot having any suitable configuration. The mini-environment 11060 may provide a controlled, clean zone for wafer transfer between multiple load port modules.

The vacuum load lock 11010 may be located between and connected to the mini-environment 11060 and the vacuum back end 11020. It is noted that the term vacuum as used herein denotes a high vacuum such as 10⁻⁵ Torr or below in which the wafers are processed. The vacuum load lock 11010 generally includes atmospheric and vacuum slot valves. The slot valves may provide the environmental isolation employed to evacuate the load lock after loading a wafer from the atmospheric front end and to maintain the vacuum in the transport chamber when venting the lock with an inert gas such as nitrogen. In one aspect, the vacuum load lock 11010 includes an aligner 11011 for aligning a fiducial of the wafer to a desired position for processing, while in other aspects alignment of the wafer is effected with the transport robot as described herein. In other aspects, the vacuum load lock may be located in any suitable location of the processing apparatus and have any suitable configuration and/or metrology equipment.

The vacuum back end 11020 generally includes a transport chamber 11025, one or more processing station(s) or module(s) 11030 and any suitable transport robot 11014. The transport robot 11014 will be described below and may be located within the transport chamber 11025 to transport wafers between the vacuum load lock 11010 and the various processing modules 11030. The processing modules 11030 may operate on the wafers through various deposition, etching, or other types of processes to form electrical circuitry or other desired structure on the wafers. Typical processes include but are not limited to thin film processes that use a vacuum such as plasma etch or other etching processes, chemical vapor deposition (CVD), plasma vapor deposition (PVD), implantation such as ion implantation, metrology, rapid thermal processing (RTP), dry strip atomic layer deposition (ALD), oxidation/diffusion, forming of nitrides, vacuum lithography, epitaxy (EPI), wire bonder and evaporation or other thin film processes that use vacuum pressures. The processing modules 11030 are connected to the transport chamber 11025 to allow wafers to be passed from the transport chamber 11025 to the processing modules 11030 and vice versa. In one aspect the load port modules 11005 and load ports 11040 are substantially directly coupled to the vacuum back end 11020 so that a substrate cassette 11050 mounted on the load port interfaces substantially directly (e.g. in one aspect at least the mini-environment 11060 is omitted while in other aspects the vacuum load lock 11010 is also omitted such that the substrate cassette 11050 is pumped down to vacuum in a manner similar to that of the vacuum load lock 11010) with a vacuum environment of the transport chamber 11025 and/or a processing vacuum of a process module 11030 (e.g. the processing vacuum and/or vacuum environment extends between and is common between the process module 11030 and the substrate cassette 11050).

Referring now to FIG. 1C, a schematic plan view of a linear processing system 2099 is shown where the tool interface section 2012 is mounted to a transfer chamber module 3018 so that the interface section 2012 is facing generally towards (e.g. inwards) but is offset from the longitudinal axis X of the transfer chamber module 3018. The transfer chamber module 3018 may be extended in any suitable direction by attaching other transport chamber modules 3018A, 3018I, 3018J to interfaces 2050, 2060, 2070 as described in U.S. Pat. No. 8,398,355, previously incorporated herein by reference. Each transfer chamber module 3018, 3018A, 3018I, 3018J includes any suitable substrate transport 2080, which may operate in accordance with aspects of the disclosed embodiment described herein, for transporting wafers throughout the linear processing system 2099 and into and out of, for example, processing modules PM. As may be realized, each chamber module may be capable of holding an isolated or controlled atmosphere (e.g. N2, clean air, vacuum).

Referring to FIG. 1D, there is shown a schematic elevation view of an exemplary processing tool 410 such as may be taken along longitudinal axis X of the linear transport chamber 416. In the aspect of the disclosed embodiment shown in FIG. 1D, tool interface section 12 may be representatively connected to the transport chamber 416. In this aspect, interface section 12 may define one end of the tool transport chamber 416. As seen in FIG. 1D, the transport chamber 416 may have another workpiece entry/exit station 412 for example at an opposite end from interface station 12. In other aspects, other entry/exit stations for inserting/removing workpieces from the transport chamber may be provided. In one aspect, interface section 12 and entry/exit station 412 may allow loading and unloading of workpieces from the tool. In other aspects, workpieces may be loaded into the tool from one end and removed from the other end. In one aspect, the transport chamber 416 may have one or more transfer chamber module(s) 18B, 18i. Each chamber module may be capable of holding an isolated or controlled atmosphere (e.g. N2, clean air, vacuum). As noted before, the configuration/arrangement of the transport chamber modules 18B, 18i, load lock modules 56A, 56 and workpiece stations forming the transport chamber 416 shown in FIG. 1D is merely exemplary, and in other aspects the transport chamber may have more or fewer modules disposed in any desired modular arrangement. In the aspect shown, station 412 may be a load lock. In other aspects, a load lock module may be located between the end entry/exit stations (similar to station 412) or the adjoining transport chamber module (similar to module 18i) may be configured to operate as a load lock.

As also noted before, transport chamber modules 18B, 18i have one or more corresponding transport apparatus 26B, 26i, which may include one or more aspects of the disclosed embodiment described herein, located therein. The transport apparatus 26B, 26i of the respective transport chamber modules 18B, 18i may cooperate to provide the linearly distributed workpiece transport system in the transport chamber. In this aspect, the transport apparatus 26B may have a general SCARA arm configuration (see also FIG. 2I, though in other aspects the transport arms may have any other desired arrangement such as, for example, an arrangement substantially similar to the transport robots 11013, 11014 of the cluster tool illustrated in FIGS. 1A and 1B, a linearly sliding arm 214 as shown in FIG. 2F or other suitable arm having any suitable arm linkage mechanisms. Suitable examples of arm linkage mechanisms can be found in, for example, U.S. Pat. No. 7,578,649 issued Aug. 25, 2009, U.S. Pat. No. 5,794,487 issued Aug. 18, 1998, U.S. Pat. No. 7,946,800 issued May 24, 2011, U.S. Pat. No. 6,485,250 issued Nov. 26, 2002, U.S. Pat. No. 7,891,935 issued Feb. 22, 2011, U.S. Pat. No. 8,419,341 issued Apr. 16, 2013 and U.S. patent application Ser. No. 13/293,717 entitled “Dual Arm Robot” and filed on Nov. 10, 2011 and Ser. No. 13/861,693 entitled “Linear Vacuum Robot with Z Motion and Articulated Arm” and filed on Sep. 5, 2013 the disclosures of which are all incorporated by reference herein in their entireties. In aspects of the disclosed embodiment, the at least one transfer arm may be derived from a conventional SCARA (selective compliant articulated robot arm) type design, which includes an upper arm, a band-driven forearm and a band-constrained end-effector, or from a telescoping arm or any other suitable arm design, such as a Cartesian linearly sliding arm, wherein any such design configuration also includes the slide body 420, alignment system 499 and end effector(s) 420A, 420B . . . 420n as described further herein. For example in one aspect the slide body 420 is mounted to an arm link of any suitable articulated transport arm. Suitable examples of transport arms can be found in, for example, U.S. patent application Ser. No. 12/117,415 entitled “Substrate Transport Apparatus with Multiple Movable Arms Utilizing a Mechanical Switch Mechanism” filed on May 8, 2008 and U.S. Pat. No. 7,648,327 issued on Jan. 19, 2010, the disclosures of which are incorporated by reference herein in their entireties. The operation of the transfer arms may be independent from each other (e.g. the extension/retraction of each arm is independent from other arms), may be operated through a lost motion switch or may be operably linked in any suitable way such that the arms share at least one common drive axis. In still other aspects the transport arms may have any other desired arrangement such as a frog-leg arm 216 (FIG. 2E) configuration, a leap frog arm 217 (FIG. 2H) configuration, a bi-symmetric arm 218 (FIG. 2G) configuration, etc. Suitable examples of transport arms can be found in U.S. Pat. No. 6,231,297 issued May 15, 2001, U.S. Pat. No. 5,180,276 issued Jan. 19, 1993, U.S. Pat. No. 6,464,448 issued Oct. 15, 2002, U.S. Pat. No. 6,224,319 issued May 1, 2001, U.S. Pat. No. 5,447,409 issued Sep. 5, 1995, U.S. Pat. No. 7,578,649 issued Aug. 25, 2009, U.S. Pat. No. 5,794,487 issued Aug. 18, 1998, U.S. Pat. No. 7,946,800 issued May 24, 2011, U.S. Pat. No. 6,485,250 issued Nov. 26, 2002, U.S. Pat. No. 7,891,935 issued Feb. 22, 2011 and U.S. patent application Ser. No. 13/293,717 entitled “Dual Arm Robot” and filed on Nov. 10, 2011 and Ser. No. 13/270,844 entitled “Coaxial Drive Vacuum Robot” and filed on Oct. 11, 2011 the disclosures of which are all incorporated by reference herein in their entireties.

In the aspect of the disclosed embodiment shown in FIG. 1D, the arms and/or end effectors of the transport apparatus 26B may be arranged to provide what may be referred to as fast swap arrangement allowing the transport to quickly swap wafers from a pick/place location. The transport arm 26B may have any suitable drive section (e.g. coaxially arranged drive shafts, side by side drive shafts, horizontally adjacent motors, vertically stacked motors, etc.), for providing each arm with any suitable number of degrees of freedom (e.g. independent rotation about shoulder and elbow joints with Z axis motion). As seen in FIG. 1D, in this aspect the modules 56A, 56, 30i may be located interstitially between transfer chamber modules 18B, 18i and define suitable processing modules, load lock(s), buffer station(s), metrology station(s) or any other desired station(s). For example the interstitial modules, such as load locks 56A, 56 and workpiece station 30i, each have stationary workpiece supports/shelves 56S, 56S1, 56S2, 30S1, 30S2 that cooperate with the transport arms to effect transport or workpieces through the length of the transport chamber along linear axis X of the transport chamber. By way of example, workpiece(s) may be loaded into the transport chamber 416 by interface section 12. The workpiece(s) may be positioned on the support(s) of load lock module 56A with the transport arm 15 of the interface section. The workpiece(s), in load lock module 56A, may be moved between load lock module 56A and load lock module 56 by the transport arm 26B in module 18B, and in a similar and consecutive manner between load lock 56 and workpiece station 30i with arm 26i (in module 18i) and between station 30i and station 412 with arm 26i in module 18i. This process may be reversed in whole or in part to move the workpiece(s) in the opposite direction. Thus, in one aspect, workpieces may be moved in any direction along axis X and to any position along the transport chamber and may be loaded to and unloaded from any desired module (processing or otherwise) communicating with the transport chamber. In other aspects, interstitial transport chamber modules with static workpiece supports or shelves may not be provided between transport chamber modules 18B, 18i. In such aspects, transport arms of adjoining transport chamber modules may pass off workpieces directly from end effector or one transport arm to end effector of another transport arm to move the workpiece through the transport chamber. The processing station modules may operate on the wafers through various deposition, etching, or other types of processes to form electrical circuitry or other desired structure on the wafers. The processing station modules are connected to the transport chamber modules to allow wafers to be passed from the transport chamber to the processing stations and vice versa. A suitable example of a processing tool with similar general features to the processing apparatus depicted in FIG. 1D is described in U.S. Pat. No. 8,398,355, previously incorporated by reference in its entirety.

Referring now to FIGS. 2A-2D the processing tool is illustrated as a linear processing tool 3000, 3000A, 3000B, 3000C having more than one cluster workstations 3010-3013 each having one or more transfer chambers 3001-3003 and a plurality of processing modules 11030 (e.g. a combination linear cluster tool). In one aspect the linear processing tool 3000, 3000A, 3000B, 3000C is substantially similar to those described in U.S. patent application Ser. No. 14/377,987 filed on Aug. 11, 2014 entitled “Substrate Processing Apparatus” the disclosure of which is incorporated herein by reference in its entirety. In one aspect the cluster workstations 3010-3013 are substantially similar to the vacuum back end 11020 described above. The cluster workstations 3010-3013 are connected to each other by one or more transfer chambers 3020, 3021 and one or more linear transfer tunnels (also referred to herein as vacuum tunnels) 3030 each having a transport robot 3033. As may be realized, each of the transfer chambers 3020, 3021 includes a transport robot 3023.

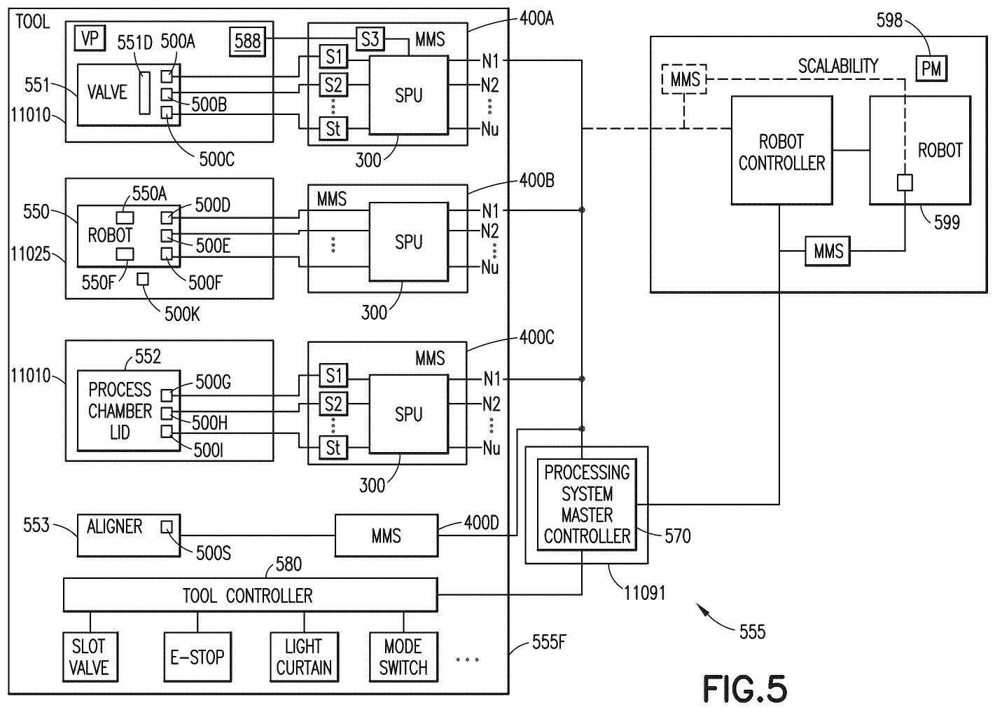

Referring to FIGS. 3, 4, 5, and 8, the least one a substrate processing station (such as process modules, aligners, etc.) and at least one substrate input or output station (e.g., load ports, load locks, etc.) of the substrate processing apparatus described herein form a substrate process echelon of the respective substrate processing system. The at least one substrate transport of the substrate processing systems described herein transport substrates or wafers S along the substrate processing echelon between the input or output station and substrate processing station, where the at least one substrate transport forms a transport echelon of the respective substrate processing system. The substrate transport apparatus 550 (which is similar to those described herein) and substrate process components (e.g., processing stations and input/output stations) of the substrate processing apparatus 555 (which may be substantially similar to the cluster and/or linear processing apparatus described herein) are communicably coupled to any suitable controller, such as controller 11091 or master controller 570 (see FIG. 5, which as noted above may be part of controller 11091). A suite of sensors including, transport echelon sensors (also referred to as arm motion sensors 566) and process echelon metrology sensors (also referred to herein as system metrology sensors 500A-500z) are communicably coupled to the controller 11091 in any suitable manner (such as described herein). The (at least one) arm motion sensors 566 is communicably coupled to the substrate transport apparatus 550 and is/are disposed to sense transport echelon predetermined characteristics (as described herein). The process echelon metrology sensors are coupled to one or more of the substrate process components (e.g., transport chambers, process modules, front end units, substrate transports, etc.) and are disposed to sense process echelon metrology predetermined characteristics (as described herein), that are different than the transport echelon predetermined characteristics.

Movement of the substrate transport apparatus is effected by the controller 11091 so as to move the arm 550A (which is similar to those described herein) to the different substrate holding positions of the substrate processing system 555 (which is similar to those described herein). The controller 11091 is communicably coupled to at least one arm motion sensor 566 and to at least one system metrology sensor 500A-500z (where “z” is an integer and denotes an upper limit on the number of system metrology sensors—see FIGS. 2E-2I, 5, and 8). As described herein, the at least one arm motion sensor 566, and the at least one system metrology sensor 500A-500z is a modular metrology sensor or station 400 having a common modular platform 496 (FIG. 4) that is selectably configurable. The at least one arm motion sensor 566 is configured to sense kinematic and/or dynamic arm motion predetermined characteristics or metrics including but not limited to acceleration, position, and velocity. The at least one system metrology sensor 500A-500z is configured to sense system metrology predetermined characteristics or metrics including but not limited to component vibrations, temperature, positions, accelerations and air flow. The system metrology predetermined characteristics are different than the kinematic and/or dynamic arm motion predetermined characteristics. The controller 11091 is configured to register data DAT, DAT2, from at least one of the at least one arm motion sensor 566 and the at least one system metrology sensor 500A-500z.

The controller 11091 is configured to effect movement of the arm 550A (via commands to the drive section 299) based on feedback from the at least one system metrology sensor 500A-500z. The feedback embodies the system metrology predetermined characteristics of one or more system components 800 (e.g., wafer handlers (e.g., robotic manipulators), slot valves, load locks, aligners, process modules, transfer modules, front end units, load ports, substrate elevators, etc.—as described herein) of the substrate processing system 555 that may affect operation of the substrate transport apparatus 550. The controller 11091 may adapt the operation of the substrate transport apparatus 550 depending on the system metrology predetermined characteristics of the system components 800. This sensor feedback is obtained from the at least one system metrology sensor 500A-500z, as raw sensing variables that are employed (as described herein) to adaptively operate the substrate transport apparatus 550 (which is similar to those substrate transport apparatus described herein). In some aspects, system metrology predetermined characteristics of the substrate transport apparatus 550 are employed by the controller along with system metrology predetermined characteristics of other different system components 800 to effect the adaptive operation of the substrate transport apparatus 550. Further, while the aspects of the disclosed embodiment are described herein as adaptively operating the substrate transport apparatus 550, the operation of other components 800 (e.g., slot valves, aligners, elevators, etc.) may be adapted based on system metrology predetermined characteristics of the substrate transport apparatus 550 as other different components 800 of the substrate processing apparatus 555.

The at least one system metrology sensor 500A-500z may be one or more of a camera(s) (line-scan, two and/or three dimensional), charge-coupled device (CCD) array(s), vibration/seismic sensor(s) (e.g., accelerometer(s)), temperature sensor(s) (e.g., infrared or otherwise), ranging sensor(s) (e.g., distance sensor such as sonar, LIDAR, time-of-flight cameras, etc.), proximity sensor(s), electrical current sensor(s), fluid flow sensor(s), magnetic sensors (e.g., Hall effect, giant magneto resistive, etc.) and any other suitable sensor(s) for measuring operating characteristics of one or more components 800 of the substrate processing system 555 (which may be substantially similar to those substrate processing systems 410, 11090, 2099, 3000, 3000A, 3000B, 3000C described herein). The at least one system metrology sensor 500A-500z is integral to or coupled with a respective component of the substrate processing system 555 in any suitable manner. It is noted that while a valve 551 (such as a slot valve) and process chamber lid 552 are illustrated in FIG. 5, along with the substrate processing apparatus 550, for exemplary purposes only, the substrate processing system 555 may have any suitable components 800 such as those described herein, each of which components 800 may include one or more metrology sensors 500A-500z.

The substrate processing system 555 includes at least one modular metrology station 400, 400A-400D. Each modular metrology station 400, 400A-400D includes respective one(s) of the at least one system metrology sensor 500A-500z and/or respective ones of the at least one arm motion sensor 566. Each modular metrology station 400 (noting that modular metrology stations 400A-400D are substantially similar) also includes a sensor processing unit 300 that is communicably coupled (wired or wirelessly) to respective ones of the at least one system metrology sensor 500A-500z. The sensor processing unit 300 can be added or removed from the substrate processing system 555 as a modular unit. For example, in one aspect the sensor processing unit 300 is mounted with one or more of the respective system metrology sensor 500A-500z on a common base 496 (FIG. 4) where remote sensor probes are integrated with and coupled to the component 800 (such as the valve 551 and process chamber lid 552—see FIG. 5); while in other aspects the system metrology sensors 500A-500z are remotely located from the sensor processing unit 300 (see FIG. 5 where the sensors are integrated with or coupled to the substrate transport apparatus 550) and communicably coupled to the sensor processing unit in any suitable manner (such as through a wired or wireless connection).

The sensor processing unit 300 includes one or more central processing units CPU1-CPUn (where n is an integer that denotes an upper limit on the number of central processing units), one or more graphics processing units GPU1-GPUm (where m is an integer that denotes an upper limit on the number of graphics processing units), field programmable gate arrays FPGA1-FPGAk (where k is an integer that denotes an upper limit on the number of field programmable gate arrays), sensor interfaces SINT1-SINTr (where r is an integer that denotes an upper limit on the number of sensor interfaces), network interfaces NINT1-NINTs (where s is an integer that denotes an upper limit on the number of network interfaces), and a memory (including one or more of non-volatile memory NVM and volatile memory VM).

The sensor processing unit is configured (e.g., with suitable non-transitory computer program code executed by one or more of the central processing units CPU1-CPUn graphics processing units GPU1-GPUm, and field programmable gate arrays) to establish hardware interfaces that are compatible with respective ones of the system metrology sensors 500A-500z (e.g., in some aspects a plug-and-play sensor interface), extract raw data from the respective system metrology sensors 500A-500z, time stamp the extracted raw data, process the raw data from each system metrology sensor so as to transform the raw data into variables of interest (e.g., for controls and diagnostic purposes), and broadcast the processed data over a network. For example, the sensor processing unit 300 includes its own operating system and communicates (using associated network protocols) with any suitable controllers (e.g., such as a robot controller, processing system master controller 570 (which may be part of or integrated with controller 11091—see FIG. 1A), a tool safety controller 580 (which may be part of or integrated with controller 11091—see FIG. 1A)) and other sensor processing units 300 over deterministic and/or non-deterministic networks including but not limited to EtherCat®, EtherNet®, and Firewire®. The sensor processing unit 300 includes one or more communication ports N1-Nu (where u is an integer that denotes an upper limit on the number of communication ports) each configured with a corresponding communication protocol to communicate over a corresponding network (e.g., EtherCat®, EtherNet®, and Firewire®, etc.).

In accordance with the disclosed embodiment, there may be different modular metrology stations 400, 400A-400D each having a different operating characteristic than another modular metrology station 400, 400A-400D so that a configuration of the different modular metrology stations 400, 400A-400D is based on the type and configuration of the component 800 to be monitored and the sensors employed to monitor the component 800. As a non-limiting example, the different operating characteristics may be a type of network the modular metrology stations 400, 400A-400D operate on. While in some aspects, the modular metrology stations 400, 400A-400D are configured to operate on a common network; in other aspects some of the modular metrology stations 400, 400A-400D are configured to operate on one network (e.g., EtherCat®, EtherNet®, and Firewire®, etc.) and others of the modular metrology stations 400, 400A-400D are configured to operate on another different network (e.g., a different one of EtherCat®, EtherNet®, and Firewire®, etc.) to effect, for example, supporting different types of hardware interfaces and different network protocols.

The modular metrology stations 400, 400A-400D are in communication with the controller 11091 to provide the data DAT2 from the at least one system metrology sensor 500A-500z in a deterministic and real-time manner while in other aspects the data DAT2 is provided asynchronously (or on demand). Here, the modular metrology stations 400, 400A-400D are configured to take data measurements (e.g., obtain the data DAT2) in association with substrate transport apparatus 550 motion, where sensor processing unit 300 of the modular metrology station 400, 400A-400D is configured to capture data from the at least one system metrology sensor 500A-500z at predetermined times. For example, the modular metrology station 400, 400A-400D data capture is triggered by or synchronized with arm 550A motion by the controller 11091 in any suitable manner. For example, controller 11091 is configured to effect broadcast of substrate transport apparatus 550 position data to the modular metrology station 400, 400A-400D, where data is captured at predetermined positions of the substrate transport apparatus 550 within the substrate transport space of the substrate processing system 555.

As an example, where the modular metrology station 400, 400A-400D includes a vision sensor (e.g., camera) positioned to capture data pertaining to an edge of the substrate S carried by the end effector EE of the substrate processing apparatus 550, the broadcast position of the substrate transport apparatus 550 informs, the modular metrology station 400, 400A-400D, of the time to capture data from the camera so that the edge of the substrate S is within a field of view of the camera coupled to the modular metrology station 400, 400A-400D. Another example is where the modular metrology station 400, 400A-400D includes a temperature sensor positioned to measure substrate S temperature(s) before and/or after substrate processing within a process module, where data is collected from the temperature sensor based on a broadcast position of the substrate transport apparatus 550 so that the substrate S is in a predetermined positioned relative to the temperature sensor to effect temperature measurement(s) of the substrate S. As a further example, the modular metrology station 400, 400A-400D is configured to capture data, based on a broadcast position of the substrate transport apparatus 550, pertaining to a time interval of vertical acceleration of the substrate S while the substrate transport apparatus is extended at a process module to pick/place the substrate S. In other aspects, the data capture of the modular metrology station 400, 400A-400D may be effected based on buffering and/or time stamped position data of the substrate transport apparatus 550 that is communicated to the modular metrology station 400, 400A-400D by the controller 11091 so that the data captured by the modular metrology station 400, 400A-400D is within predetermined ranges of interest of the substrate transport apparatus 550 position.

As described above, the modular metrology station(s) 400, 400-400D includes one or more processing units (e.g., central processing units CPU1-CPUn, graphics processing units GPU1-GPUm, and/or field programmable gate arrays FPGA1-FPGAk) and memory (e.g., non-volatile memory NVM and/or volatile memory VM). As also described herein, the modular metrology station(s) 400, 400A-400D are coupled to the controller 11091 where the one or more processing units and memory of the modular metrology station(s) 400, 400A-400D may off-load or transfer memory and computational loads from the controller 11091 to the modular metrology station(s) 400, 400A-400D. Here, the modular metrology stations 400, 400A-400D may effect simplification of the controller 11091 (software and/or hardware) configuration/architecture (e.g., via the off-loading of memory and computation loads) and effect additional sensing/feedback near, for example a process module or other component 800 (such as substantially direct position feedback of the substrate within the substrate processing system 555), so as to provide an increased system data gathering capacity for system diagnosis and machine learning. In accordance with the disclosed embodiment, employment of the modular metrology stations 400, 400A-400D may provide a framework to generate encapsulated objects or defined classes (as in object oriented programming) where each modular metrology station 400, 400A-400D is represented within the controller 11091 software as an object. In some aspects, the modular metrology station 400, 400A-400D can be defined within an EtherCat® protocol context as part of a semiconductor device profile.

Still referring to FIG. 5, as described above, the controller 11091 is communicably coupled to the transport echelon sensors (e.g., arm motion sensor(s) 566) and the metrology echelon sensors (e.g., system metrology sensors 500A-500z), and is configured to generate, from the sensor data DAT, DAT2 embodying both the transport echelon predetermined characteristics (as described herein), and the process echelon metrology predetermined characteristics (as described herein), a set of predetermined functional characteristic indices (described herein), each index corresponding to a different respective predetermined functional characteristic, of the substrate transport apparatus 550 transporting the substrate S or of the substrate processing echelon, and informing a relationship between the respective predetermined functional characteristic and the motion quality of the substrate S transported by the substrate transport apparatus 550. As described in further detail herein, the controller 11091 is configured to determine from the set of predetermined functional characteristic indices an integral holistic measure index (e.g., wafer motion quality index WMQIdx) of holistic motion quality of the substrate S transported by the substrate transport apparatus 550.

The controller 11091 is configured to register data DAT, DAT2, from at least one of the at least one arm motion sensor 566 and the at least one system metrology sensor 500A-500z. The controller 11091 is configured to determine from the registered data an operative value for each different respective predetermined functional characteristic and factor the operative value with respect to a corresponding reference value for each different predetermined functional characteristic. For example, the controller 11091 determines from the registered data DAT, DAT2 a set of predetermined functional characteristic indices or values (as described herein), where each index corresponds to a different respective predetermined functional characteristic, of arm motion transporting the substrate or of the system, and informs a relationship between the respective predetermined functional characteristic and a motion quality of the substrate S transported by the movable arm 550A. Each of the different predetermined functional characteristics is dependent on at least one unique control parameter of the arm 550A, or the system 555, controlled by controller 11091 commands.

As described herein, the controller 11091 is configured to determine from the set of predetermined functional characteristic indices an integral or combined holistic measure index or value (e.g., wafer motion quality index WMQIdx) of holistic motion quality of the substrate S transported by the movable arm 550A. Here, the aspects of the disclosed embodiment provide metrics or characteristics for the wafer motion quality and the employment of such metrics to adapt the substrate transport apparatus 550 motion controls, based on the metrics, to maximize tool throughput and tool uptime (e.g., operation of the tool).

As described herein, the respective predetermined functional characteristic includes at least one of a substrates processed per hour (WPH), position loop servos Gain Margin (GM), position loop servos Phase Margin (PM), Wafer Handling Error (WHE), Wafer Slippage (WS), Settling Time (ST), Wafer Handoff Vibration (WHV), Wafer Motion Wobble (WWE), and Wafer Motion Vibration (WMV). As also described herein, the set of predetermined functional characteristic indices includes an index for at least one of the respective predetermined functional characteristic that includes at least one of substrates processed per hour (WPH), position loop servos Gain Margin (GM), position loop servos Phase Margin (PM), Wafer Handling Error (WHE), Wafer Slippage (WS), Settling Time (ST), Wafer Handoff Vibration (WHV), Wafer Motion Wobble (WWE), and Wafer Motion Vibration (WMV). At least one of the system metrology predetermined characteristics is derivative of (e.g., dependent on) arm motion (or arm motion predetermined characteristics).

The wafer motion quality index WMQIdx represents a performance index or cost function of the substrate processing system 555 operation in terms of substrate handling performance variables such that a value of the wafer motion quality index WMQIdx is indicative of a substrate health (or a substrate health index) of the substrate processing system 555. A maximization of the wafer motion quality index WMQIdx maximizes the operating efficiency/performance of the substrate processing system 555. The wafer motion quality index WMQIdx is defined by motion automation variables that can be dynamically altered or adapted, such as through an adaptation component or control law (and associated parameters/gains) effected by the controller 11091, to maximize the wafer motion quality index WMQIdx. The wafer quality index WMQIdx is defined, as in equation [1], by substrate processing tool 555 performance variables that substantially directly impact the quality of the substrate S handling operation within the substrate processing tool 555.

$$WMQIdx = \frac{( WPHIdx ) ( GMIdx ) ( PMIdx ) ( WMVIdx )}{( WWEIdx ) ( WSIdx ) ( STIdx ) ( WHVIdx ) ( WWEIdx )} \qquad [ eq . 1 ]$$

where, WPHIdx is a wafers processed per hour index, GMIdx is a position loop servos gain margin index, PMIdx is a position loop servos phase margin index, WHEIdx is a wafer handling error index, WSIdx is a wafer slippage index, STIdx is a settling time index, WHVIdx is a wafer handoff vibration index, WWEIdx is a wafer motion wobble index, and WMVIdx is a wafer motion vibration index. The aforementioned indices are normalizations of the associated metrics/characteristics such that indices above 1 indicate the associated variable is performing above its nominal (e.g., reference) value. The aforementioned indices are defined as follows:

$$WPHIdx = {k}_{WPH \frac{WPH}{{WPH}_{ref}}} \qquad [ eq . 2 ]$$

$$GMIdx = {k}_{GM} \frac{GM}{{GM}_{min}} \qquad [ eq . 3 ]$$

$$PMIdx = {k}_{PM} \frac{PM}{{PM}_{min}} \qquad [ eq . 4 ]$$

$$WHEIdx = {k}_{WHE} \frac{WHE}{{WHE}_{max}} \qquad [ eq . 5 ]$$

$$WSIdx = {k}_{WS} \frac{WS}{{WS}_{max}} \qquad [ eq . 6 ]$$

$$STIdx = {k}_{ST \frac{ST}{{ST}_{max}}} \qquad [ eq . 7 ]$$

$$WHVIdx = {k}_{WHV \frac{WHV}{{WHV}_{max}}} \qquad [ eq . 8 ]$$

$$WWEIdx = {k}_{WWE} \frac{WWE}{{WWE}_{max}} \qquad [ eq . 9 ]$$

$$WMVIdx = {k}_{WMV \frac{WMV}{{WMV}_{max}}} \qquad [ eq . 10 ]$$

where, WPH is the current number of processed wafers per hour, WPH_{ref} is the nominal (reference) number of processed wafers per hour, GM is the motion servo stability gain margin, GMₘᵢₙ is the minimum acceptable motion servo stability gain margin, PM is the motion servo phase margin, PMₘᵢₙ is the minimum acceptable motion servo stability phase margin, WHE is the wafer handoff error, WHEₘₐₓ is the maximum acceptable wafer handoff error, WS is the wafer slippage at the substrate transport apparatus 550 end effector EE (see, e.g., FIGS. 2E-2I), WSₘₐₓ is the maximum acceptable wafer slippage at the substrate transport apparatus 550 end effector EE, ST is the motion settling time of the substrate transport apparatus 550, STₘₐₓ is the maximum acceptable motion settling time of the substrate transport apparatus, WHV is the wafer handoff vibration, WHVₘₐₓ is the maximum acceptable wafer handoff vibration, WWE is the wafer motion wobble (e.g., of the arm with the arm extended at a substrate holding station), WWEₘₐₓ is the maximum acceptable wafer motion wobble (e.g., of the arm with the arm extended at a substrate holding station), and WMV is the wafer motion vibration, WMVmax is the maximum acceptable wafer motion vibration, and kᵥₐᵣ is a weight from 0 to 1 associated with respective variables noted above (e.g., k_{wph} is a weight associated with the current number of processed wafers per hour, k_{GM} is a weight associated with the motion servo stability gain margin, etc.).

The wafers per hour WPH is determined in any suitable manner, such as by the average period between two processed wafers exiting the substrate processing apparatus 555. The wafers per hour WPH represents a flow of wafers or substrates S from/to the substrate processing apparatus 555 to/from the load locks (see, e.g., FIG. 1A and load locks 11010 and other load locks described herein).

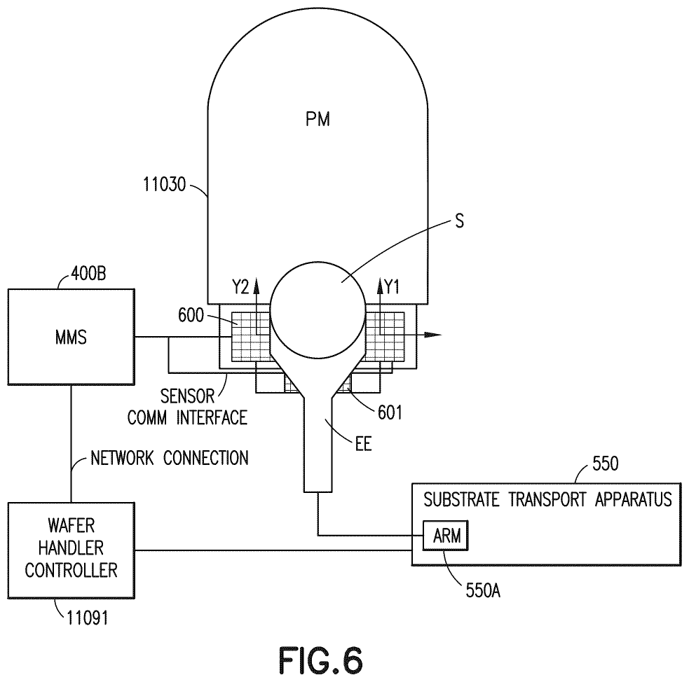

The wafer handoff error WHE is defined by a difference in reported wafer offsets (such as from any suitable position feedback system of the substrate processing apparatus, including but not limited to a modular metrology station 400B including an on-the-fly substrate centering sensor—see FIG. 6) between subsequent pick (or place) operations from the same substrate holding station. FIG. 6 illustrates a modular metrology station 400B having at least one two dimensional and/or three dimensional position sensors 600, 601 (e.g., cameras, CCD arrays, etc.) and configured to determine pick place offsets of the substrate S relative to the end effector EE of the substrate transport apparatus 550 arm 550A. Other suitable examples of on-the-fly substrate sensors that may be employed with the aspects of the disclosed embodiment are described in, for example, U.S. Pat. No. 6,556,887 issued on Apr. 29, 2003, U.S. Pat. No. 6,990,430 issued on Jan. 24, 2006, and U.S. Pat. No. 10,134,623 issued on Nov. 20, 2018, the disclosures of which are incorporated herein by reference in their entireties. An increasing trend between reported pick (and/or place) wafer offsets from the same substrate holding station may be an indication of wafer handoff errors.

The wafer slippage WS at the end effector EE (see, e.g., FIGS. 2E-2I) is defined as the amount of measurable substrate or wafer S slippage between the wafer S and the end-effector EE of the arm 550A as a result of arm 550A acceleration or vibration. Wafer slippage WS may be measured in any suitable manner, such as by comparing the reported wafer offsets (as noted above) reported between a pick and place operations between an origin (i.e., picked from) substrate holding station and a destination (i.e., placed to) substrate holding station. An increasing trend in the difference between the respected reported wafer offsets (e.g., the pick and place wafer offsets) may be an indication of wafer slippage on the end effector EE.

Motion settling time ST of the substrate transport apparatus 550 (such as of the arm 550A) is defined as the time between the end of a commanded arm motion and the time it takes for motion servo loop errors to settle within a predetermined tolerance. It is noted that the motion settling time ST would be zero if the motion servo loop errors were within their respective tolerances by the time the commanded motion ends; however, generally the predetermined tolerances are defined as the allowable settling error limits for position and velocity errors of each of the motion axes. The motion of the arm 550A is complete (e.g., settled) where the position and velocity errors for each of the motion axes are substantially simultaneously within the predetermined tolerances. An increasing trend in the motion settling time ST may indicate changes to the mechanical behavior of the substrate transport apparatus 550 such as increased friction or vibration.

The motion servo stability gain margin GM and the motion servo stability phase margin PM are and may be determined in any suitable manner such as with Bode plots. In accordance with the aspects of the disclosed embodiment the servo loops of each axis of motion of the substrate transport apparatus 550 are tuned so that the gain and phase stability margins are maximized and to account for variations of the substrate transport apparatus 550 operation effected by mechanical and/or environment operating conditions including, but not limited to, temperature gradients, thermal stress, bearing wear, and changes in transmission band tension. A decrease in the motion servo stability gain margin GM and the motion servo stability phase margin PM below minimum predetermined thresholds may present, in substrate transport apparatus 550 operation, motion quality symptoms (e.g., such as motion vibration and wafer slippage) and/or maintenance alerts being presented to an operator.

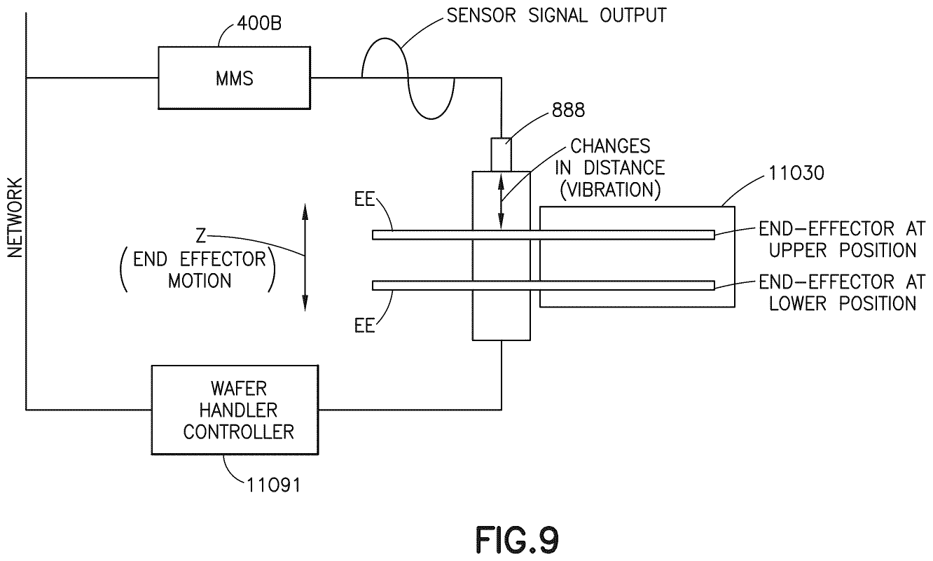

Wafer or substrate handoff vibration WHV is defined as a peak to peak tracking error of end effector EE motion during a wafer handoff operation (e.g., the vertical lift or lower motion of the wafer relative to a substrate holding station along a vertical Z axis of travel—see FIG. 9) at a respective substrate holding station. The substrate handoff vibration may be determined in any suitable manner such as by substantially directly measuring a point on the substrate S or end effector EE (with any contact or non-contact sensor, e.g., optical sensors, accelerometers, etc.) during the lift or lower movement of the substrate transport apparatus 550 arm 550A. Referring also to FIG. 9, a modular metrology station 400B is illustrated as having at least one distance measurement sensor 888 (e.g., optical laser sensor, etc.). The modular metrology station 400B having the at least one distance measurement sensor 888 is configured to sense changes in distance of the substrate S and/or end effector EE (e.g., relative to the motion of the substrate S or end effector along the Z axis of travel) that are indicative of substrate/end effector vibration. Here, the modular metrology station 400B may employ a power spectral density (or its integral over a frequency range) analysis of the at least one distance measurement sensor 888 output obtained with the substrate S and/or end effector EE movement along the Z axis of travel to determine the wafer handoff vibration WHV, noting in other aspects any suitable sensor/sensor analysis may be employed by the modular metrology station 400B to determine the wafer handoff vibration WHV. The wafer motion wobble WWE is defined as a maximum deviation error between a commanded trajectory of the wafer S and an actual trajectory of the wafer S at a predetermined wafer S entry point of a substrate processing module 11030. Referring again to FIG. 6, the modular metrology station 400B including the position sensors 600, 601 may also be employed to effect the measurements of wafer motion wobble WWE. Here, the modular metrology station may provide real time feedback of the wafer S position in space with the employment of wafer position measurements and end effector perimeter position measurements versus a reported (such as by any suitable drive section 299 encoders 299E) position of the arm 550A. The modular metrology station 400B may be in communication with the controller 11091 over any suitable deterministic network (such as those described herein) to effect real time feedback of the wafer S path and calculation of the wafer motion wobble WWE error.

The wafer motion vibration WMV is a measurement of the vibration of the wafer S during motion of the wafer S between substrate holding stations (e.g., between one or more of load ports, process modules, load locks, aligners, etc.). The wafer motion vibration WMV may be measured in any suitable manner where, for example, the wafer motion vibration WMV is defined as a peak value of the compound acceleration error among wafer transfers that effect processing one wafer cycle. In other aspects, the wafer motion vibration WMV may be determined by a root-mean-square of the compound acceleration error among the wafer transfers that effect processing of one wafer cycle. In still other aspects, the wafer motion vibration WMV is defined as a summation of power spectral density magnitudes of a motion acceleration or torque values across a prescribed range of frequencies for the wafer transfers that effect processing one wafer cycle.

Table 1 below indicates the correlation between the above-noted predetermined arm motion characteristics/metrics (motion automation variables) and a respective control parameter that may be employed in association with a given predetermined arm motion characteristic/metric.

TABLE 1

| Performance Metrics | Symbol | Proposed Control Parameters |
|---|---|---|
| Wafers Processed | WPH | Trajectory planning axis limits for |
| Per Hour | | velocity, acceleration and jerk. |
| | | Motion path into a station. |
| | | Optimization of Via Point locations |
| | | and blending distances to |
| | | maximize motion throughput. |
| | | Optimal location of retract position |
| | | upon pick and place operations. |
| Wafer Handoff | WHE | Jerk and acceleration hand off |
| Error | | motion limits of vertical axis (Z) |
| | | at the respective station. |
| Wafer Slippage | WS | Jerk and acceleration extend/ |
| | | retract/rotate motion limits |
| | | at/between respective stations. |
| | | Velocity limits of vertical axis |
| | | (Z) moves between stations. |
| Motion Settling | ST | Jerk motion limit during extend |
| Time | | motion to respective station. |
| Servo Gain | GM | Closed loop control loop gain |
| Margin Stability | | (position servo bandwidth) |
| | | of respective motion axis. |
| | | Location of poles and zeros of |
| | | control output Bi-Quad filters. |
| Servo Phase | PM | Closed loop control damping factor. |
| Margin Stability | | Location of poles and zeros of control |
| | | output Bi-Quad filters. |
| Wafer Handoff | WHV | Same parameters as in WHE. |
| Vibration | | |
| Wafer Wobble | WWE | Dynamic model feasible Base |
| at Extend | | Parameter Set a suitable example |
| | | of which is described in Jia J. et |
| | | al., Dynamic Parameter Identification |
| | | for a Manipulator with Joint |
| | | Torque Sensors Based on an |
| | | Improved Experimental Design, |
| | | Sensors 2019, 19, 2248; doi: |
| | | 10.3390/s19102248, the disclosure |
| | | of which is incorporated herein |
| | | by reference in its entirety. |
| Wafer Motion | WMV | Closed loop control damping factor |
| Vibration | | Location of poles and zeros of |
| | | control output Bi-Quad filters |

As described above, the wafer motion quality index WMQIdx is defined by motion automation variables that can be dynamically altered or adapted, such as through an adaptive component or control law (and associated parameters/gains) effected by the controller 11091, to maximize the wafer quality index WMQIdx. Here, the controller 11091 is programmed with the adaptive control and/or machine learning-based law that commands changes in control parameters so as to generate the maximum wafer quality index WMQIdx (e.g., maximum holistic measure index), or minimize progression of adverse changes (as described herein) of the wafer quality index WMQIdx. The adaptive control and/or machine learning-based law adjusts the, e.g., the above-noted control parameters shown in Table 1 to effect maximization of the substrate processing apparatus 550 wafer motion quality index WMQIdx. It is noted that the adaptive control and/or machine learning-based law (described herein and in the examples provided below) may be effected at least in part by the controller 11091; however, as noted above, computations and/or memory may be offloaded from the controller 11091 to the modular metrology stations 400, 400A-400D described herein so that the modular metrology stations 400, 400A-400D may effect some of the computations and/or provide memory to effect the adaptive control and/or machine learning-based law.

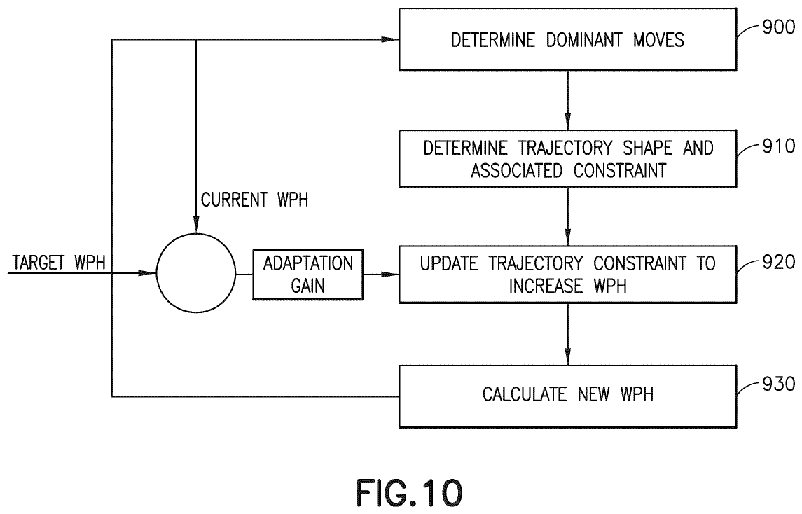

For exemplary non-limiting purposes only, the wafer per hour WPH can be adjusted by the controller 11091 by modifying motion trajectory constraints as indicated (for exemplary purposes) in Table 1. The type of constraint (or limit) to be changed depends on a type of trajectory shape selected to perform motion of the arm 550A, such as described in U.S. Pat. No. 6,216,058 issued on Apr. 10, 2001, the disclosure of which is incorporated herein by reference in its entirety. The adaptive control and/or machine learning-based law is configured to determine which motion, of different types of motions the arm 550A may perform to transfer a wafer S, has the highest impact on the wafers per hour WPH metric. FIG. 10 is an exemplary flow diagram that illustrates adaptation of the wafers per hour WPH of the substrate processing apparatus 550 based on, for example, the respective control variables described herein. For exemplary purposes of FIG. 10, the radial extend move of the arm 550A into the station for a place operation (with a wafer S on the end effector EE) is determined to have substantially a highest impact (e.g., is a dominant move) on the wafers per hour WPH at each substrate holding station of the substrate processing apparatus 550 (FIG. 10, Block 900). Also for exemplary purposes only, the trajectory shape for the radial extend move at each substrate holding station is determined as an acceleration limited trajectory shape (FIG. 10, Block 910). In this example, to improve the wafers per hour WPH by about 10% the adaptation control law may increase the acceleration limit by a similar proportion of about 10% and measure (with the modular metrology stations 400, 400A-400D) the response of the other performance indexes (e.g., noted above) to the increase in the acceleration limit (FIG. 10, Block 920) and a new wafers per hour is calculated (FIG. 10, Block 930). Blocks 900-930 in FIG. 10 may continue in a loop (e.g., a systematic increase of the acceleration limit) until the wafer motion quality index WMQIdx reaches an inflection point where the wafer motion quality index WMQIdx begins to decay. For example, if the acceleration limit becomes too high, despite improving the wafers processed per hour index WPHIdx, the wafer slippage WS may reach a point where the wafer slippage WS becomes unacceptable causing an increase in the wafer slippage index WSIdx and as a result a decrease of the overall wafer motion quality index WMQIdx.

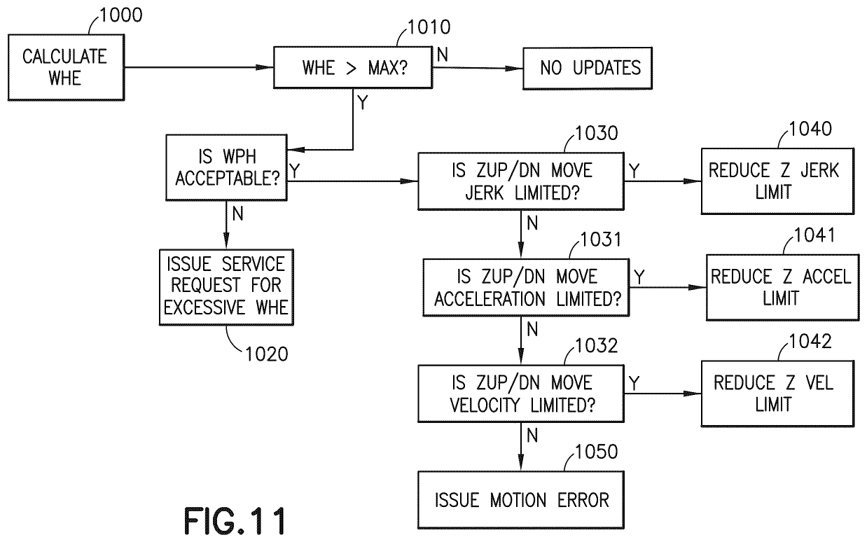

Referring also to FIG. 11 an exemplary flow diagram of an adaptation control law for minimizing the Wafer Handling Error WHE is illustrated. A similar approach to that illustrated in FIG. 11 may be employed for minimizing other system level characteristics/metrics (and associated indices) such as, e.g., the wafer slippage WS, the settling time ST, the wafer handoff vibration WHV, and the wafer motion wobble WWE. In the example illustrated in FIG. 11, the wafer handling error WHE is calculated/determined (e.g., as described above with respect to modular metrology station 400B illustrated in FIG. 6) (FIG. 11, Block 1000) and it is determined (e.g., by the modular metrology station 400B or the controller 11091) whether the wafer handling error WHE exceeds a predetermined maximum acceptable threshold (FIG. 11, Block 1010). Where the wafer handling error WHE exceeds the predetermined maximum acceptable threshold and the wafer handling error WHE is not within acceptable limits (e.g., the acceptable limits being above the predetermined maximum acceptable threshold) the controller 11091 effects issuance of a service request to an operator of the substrate processing apparatus 550 (FIG. 11, Block 1020). Where the wafer handling error WHE exceeds the predetermined maximum acceptable threshold and the wafer handling error WHE is within the acceptable limits constraints on the Z axis motion of the wafer S are identified (FIG. 11, Blocks 1030-1032). For example, where the motion of the wafer S along the Z axis is jerk limited, the jerk limit may be decreased to reduce the amount of wafer handling error WHE (FIG. 11, Block 1040). Where the motion of the wafer S along the Z axis is acceleration limited, the acceleration limit may be decreased to reduce the amount of wafer handling error WHE (FIG. 11, Block 1041). Where the motion of the wafer S along the Z axis is velocity limited, the velocity limit may be decreased to reduce the amount of wafer handling error WHE (FIG. 11, Block 1042). The controller 11091 or modular metrology station 400, 400A-400D may determine, in any suitable manner (e.g., upon a decrease in one or more of the jerk limit, the acceleration limit, and the velocity limit) if the productivity of the substrate processing apparatus is within acceptable limits, and if not, the controller 11091 may issue a service request error (FIG. 11, Block 1050) to an operator of the substrate processing apparatus 550.

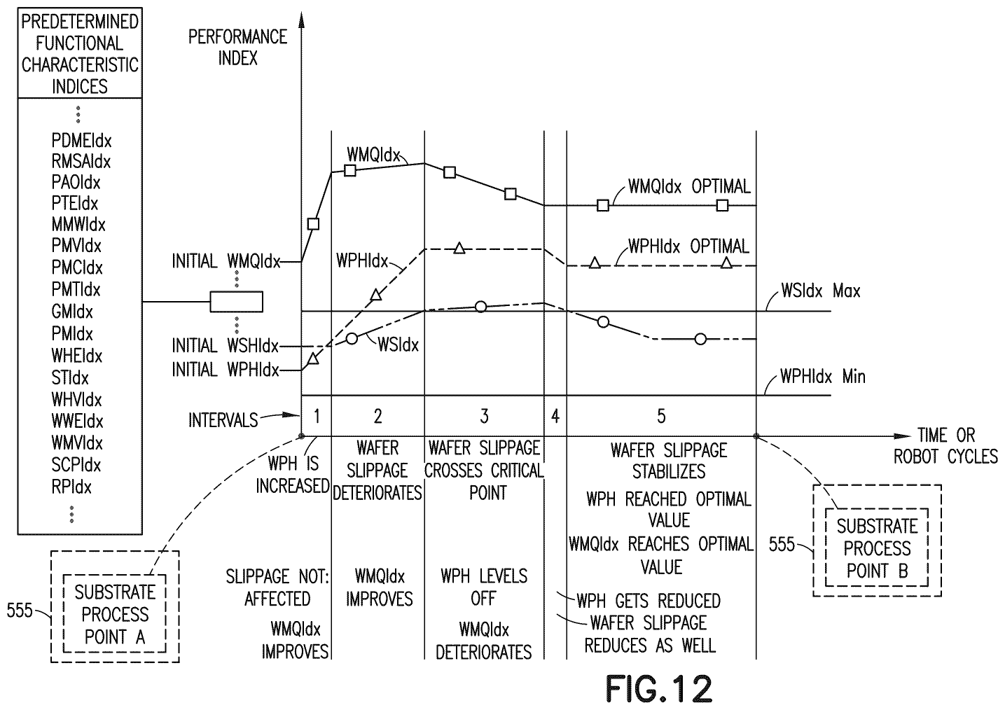

Referring to FIG. 12, an exemplary graph illustrating the adaptation of the predetermined functional characteristic indices and their respective variables to effect maximization of the wafers processed per hour index WPHIdx is illustrated; however, it should be understood that the exemplary graph is representative of the maximization/minimization of any one or more of the predetermined functional characteristic indices (and their respective variables) described herein and the maximization of the wafer motion quality index WMQIdx. It is noted that the exemplary graph of FIG. 12 is also representative of the maximization/minimization of any one or more of the predetermined functional characteristic indices (and their respective variables) described herein and the maximization of the wafer motion quality index WMQIdx between any suitable process/holding locations of the substrate processing apparatus 555 and any of the substrate process apparatus illustrated in FIGS. 1A-2D. For example, referring to FIG. 1A the adaptation of the predetermined functional characteristic indices described herein and their respective variables may be employed to the substrate processing apparatus 11090 in total (e.g., from the load ports 11040 through the substrate processing apparatus (according to a predetermined substrate processing recipe) and back to the load ports 11040). The adaptation of the predetermined functional characteristic indices described herein and their respective variables may also be employed between any two points in processes performed by the substrate process apparatus 11090, such as between the load ports 11040 and load locks 11010 through the mini-environment (front-end unit) 11060, between the load locks 11010 and a process module 11030, etc. As may be realized from FIG. 12 and its description, each of the predetermined functional characteristic indices are capable of being varied so that variance of one or more of the predetermined functional characteristic indices is performed collectively to maximize the wafer motion quality index WMQIdx.

In the graph illustrated in FIG. 12 the effect of the maximization of the wafers processed per hour index WPHIdx on the wafer slippage index WSIdx and the wafer motion quality index WMQIdx is illustrated for exemplary purposes only, noting that any one or more of the predetermined functional characteristic indices may be varied in a manner substantially similar to that described herein. The exemplary graph is divided into 5 intervals which, as described above may be intervals within a movement of the substrate or wafer S between any two or more points in one or more processes performed by the substrate process apparatus 11090 (referred to in FIG. 12 as substrate process points A and B). In other aspects, the intervals may be time intervals or intervals of any suitable number of robot cycles. In interval 1 the substrate transport apparatus 550 is controlled so that arm 550A acceleration is increased so as to increase the wafers processed per hour index WPHIdx. In interval 1 the wafer slippage index WSIdx and the wafer motion quality index are substantially unaffected by the increase in the wafers per hour. In interval 2, wafer slippage occurs (i.e., the wafer slippage index WSIdx increases) lowering the wafer motion quality index WMQIdx; however, the wafer slippage remains within acceptable levels. In interval 3, the wafer slippage reaches unacceptable levels as the respective wafer slippage index WSIdx crosses the predetermined maximum threshold WSIdxₘₐₓ while the wafer per hour index WPHIdx rate is brought zero. In interval 4, the controller 11091 slows down motion of the substrate transport apparatus 550 arm 550A to bring the wafer slippage to within acceptable levels, where the wafer motion quality index WMQIdx decreases from the slowed motion of the arm 550A. In interval 5, wafer slippage index WSIdx and the wafers per hour index WPHIdx are stabilized to optimal levels to effect the optimal wafer motion quality index WMQIdx given the condition of the substrate processing apparatus 555 in time interval 5. This adaptation process to maximize the wafer motion quality index WMQIdx may be continued (e.g., in a substantially loop by the controller 11091 with data from one or more modular metrology stations 400, 400A-400D) to a point in time where wafer slippage is no longer manageable while maintaining an acceptable wafer per hour WPH metric, at which point the controller 11091 issues a service call to an operator of the substrate processing apparatus 555 for servicing of the substrate transport apparatus 550.

As described above and still referring to FIG. 5, more than one modular metrology station 400, 400A-400D may be included in the substrate processing apparatus 555. The modular metrology stations 400, 400A-400D may gather process information from the substrate transport apparatus 550, isolation valves 551, process chambers (such as with sensors located on the process chamber lid 552), and any other substrate processing equipment (e.g., aligners, slot valves, substrate elevators, load locks, load ports, front end units/fan filter units, vacuum gauges, etc.). This data from the above-mentioned various substrate processing equipment may provide the controller 11091 with respective system level variables that may be employed to effect the maximization of the wafer motion quality index WMQIdx. Table 2 below provides an exemplary summary of additional system level variables or predetermined functional characteristics in terms of the respective discrete automation components of the substrate processing apparatus 550.

TABLE 2
Automation Components and System Level Variables:

| Automation | |
|---|---|
| Component | System Level Variable |
| Load Locks | Pump and Vent times; |
| | Vertical lift motion times; |
| | Vibration signatures during vertical motion. |
| Slot Valves | Time interval between opening and closing; |
| | Time interval between subsequent openings; |
| | Time stamps upon opening and closing; |
| | Vibration signatures during opening and closing. |
| Wafer Aligners | Wafer Align Times; |
| | Historical wafer offsets and fiducial locations. |
| Temperature | Wafer temperature before placing and after picking |
| Sensors | from a Process Module; |
| | Robot flange and arm components temperatures. |
| Vacuum Gauges | Vacuum level. |
| Fan Filter Units | Air flow from Fan Filter Unit. |

Each of the system level variables listed in Table 2 may have an associated performance index in a manner similar to that described above equations [2] to [10]. As a result, a System Component Performance Index SCPIdx can also be incorporated into the definition of equation [1], such as added to the numerator of the fraction. In accordance with the aspects of the disclosed embodiment, the controller 11091 monitors the holistic measure index (e.g., the wafer motion quality index WMQIdx), identifies trends therein, and adaptively generates commands that effect changes to the control parameter varying the dependent predetermined functional characteristic and its corresponding index in response to the identified trends. For example, load locks (such as load locks 11010-FIG. 1A) may be the entry and exit point of wafers S in the substrate processing apparatus 555, where the environment of the load locks alternates between vacuum and atmospheric pressure. Pump and vent times (e.g., as determined from pressure gauges 588 of, for example, modular metrology system 400A) are performance parameters for substrate processing apparatus 555 productivity that can be measured and tracked over time to detect trends of increased process times of the load lock 11010. The pump and vent time deviations or trends may be employed by the controller 11091 to control the load lock to alter opening and closing isolation valve times to compensate for increases in the load lock processing times. Another possible adaptation of the load lock 11010 may be alterations/adaptations (e.g., by the controller 11091 employing the adaptive control and/or machine learning-based law) of the motion timing of a vertical lift mechanism of a wafer support within the load lock that controls the vertical/lift motion of the wafer within the load lock.

As another example, of adaptive control and/or machine learning-based law, the controller 11091 monitors changes in the holistic measure index (e.g., the wafer motion quality index WMQIdx) from transients in at least one index of a respective predetermined functional characteristic responsive to controller commands changing a control parameter determinative of the respective predetermined functional characteristic. For example, the opening and closing time intervals of the slot valves 551 may be employed as performance metrics for wafer process times of the substrate processing apparatus 555. As may be realized, the opening and closing time intervals of the slot valves 551 may also be indicative of slot valve seal wear. For example, changes in the slot valve 551 opening and closing time intervals can be an indication of required maintenance of the O-ring (or other suitable) seal that is part of the isolation apparatus. The slot valve 551 opening and closing time intervals may decrease the tool performance if a positive trend is observed in the time period it takes to open and close the slot valves 551. Here, this slot valve opening and closing time intervals and trends thereof (e.g., as obtained by the modular metrology stations 400A and suitable sensors 500A-500C thereof) may be employed by the controller 11091 to dynamically change a trajectory profile of a door 551D of the slot valve 551 to compensate for changes in the slot valve opening and closing time intervals to offset any adverse change to the wafer motion quality index WMQIdx.

The controller 11091 monitors changes in the wafer motion quality index WMQIdx from transients in at least one index of a respective predetermined functional characteristic and in response to a predetermined adverse change of the wafer motion quality index WMQIdx commands a change in a control parameter determinative of another respective predetermined functional characteristic that offsets, at least in part, the predetermined adverse change of the wafer motion quality index WMQIdx. For example, in the slot valve example described above, the controller 11091 may also (or in lieu of changing a trajectory profile of a door 551D of the slot valve 551 to compensate for changes in the slot valve opening and closing time intervals) modify (e.g., accelerate) the motion of the substrate transport apparatus 550 in a way to compensate for delays induced by the reduced slot valve 551 performance and offset any adverse change to the wafer motion quality index WMQIdx.

The controller 11091 is configured to compare a change in the wafer motion quality index WMQIdx from the transients in the at least one predetermined functional characteristic index (e.g., such as from one of wafers processed per hour index WPHIdx, position loop servos gain margin index GMIdx, position loop servos phase margin index PMIdx, wafer handling error index WHEIdx, wafer slippage index WSIdx, settling time index STIdx, wafer handoff vibration index WHVIdx, wafer motion wobble index WWEIdx, and wafer motion vibration index WMVIdx) relative to another change in the wafer motion quality index WMQIdx from other different transients in at least another different predetermined functional characteristic index (e.g., such as from a different one of wafers processed per hour index WPHIdx, position loop servos gain margin index GMIdx, position loop servos phase margin index PMIdx, wafer handling error index WHEIdx, wafer slippage index WSIdx, settling time index STIdx, wafer handoff vibration index WHVIdx, wafer motion wobble index WWEIdx, and wafer motion vibration index WMVIdx), and from the comparison of relative changes in the wafer motion quality index WMQIdx by the transients and by the other different transients, scale the at least one predetermined functional characteristic index and the at least another different predetermined functional characteristic index relative to each other. For example, referring to equations [2]—the controller 11091 may adjust the weight kᵥₐᵣ of the at least one predetermined functional characteristic index and the at least another different predetermined functional characteristic index relative to each other so that each of the at least one predetermined functional characteristic index and the at least another different predetermined functional characteristic index relative to each other and the wafer motion quality index WMQIdx are optimized.

In accordance with the aspects of the disclosed embodiment, the modular metrology stations 400, 400A-400D and the adaptive control and/or machine learning-based law described herein provide the substrate processing apparatus 555 (and the components thereof) with monitoring of an occurrence of vibration and timing of vibration sources that are either self-induced or external. For example, with respect to effects of vibration on the substrate transport apparatus 550, it is noted that slot valve opening and closing may generate a vibration impulse that may impact the quality of the wafer motion in the substrate processing apparatus 555. The modular metrology stations, such as modular metrology station 400A, may capture the vibration information (e.g., with suitable sensors 500A-500C) in conjunction with slot valve 551 actuation timing and/or time stamp the capture of the vibration information. The robot controller, such as controller 11091 may control the substrate transport apparatus 550 so that high accuracy wafer placement by the substrate transport apparatus does not occur during actuation of the slot valve 551, where the slot valve 551 is part of a substrate processing station that is not associated with the high accuracy wafer placement. Here, the high accuracy wafer placements may be effected during “quiet” times, i.e. performed at times that are not subjected to the vibration of slot valve 551 actuation from anywhere within the substrate processing apparatus 555. In other aspects, other vibrations from sources external to the substrate transport apparatus 550, such as from vacuum pumps VP (such as from load lock 11010 and/or a process module 11030), may be detected by position sensors (such as drive section 299 encoders 299E—see FIGS. 2E-2I) and processed within the controller 11091 (or a modular metrology station 400B) to quantify the effect of the external vibrations on the position servo loop performance of the substrate transport apparatus 550. Here, the controller 11091 may, with the adaptive control and/or machine learning-based law, make changes to servo loop filter parameters (such as, e.g., Bi-Quad filters) to attenuate the servo loop response to the external vibration coming from the vacuum pumps.

In accordance with the aspects of the disclosed embodiment, the modular metrology stations 400, 400A-400D and the adaptive control and/or machine learning-based law described herein provide the substrate processing apparatus 555 with monitoring of aligner 553 wafer align time performance. In a manner similar to that noted above, with respect to the slot valves 551, wafer align times may be affected by degradation of aligner 553 components such as wafer support (backside or edge contact) pads. Here, the wafer align times may decrease productivity of the substrate process apparatus 555 where an upward trending is observed in the wafer align times. The wafer align times, as measured by suitable sensors 500J of modular metrology station 400D are employed by the controller 11091 to dynamically adapt/alter motion performance (e.g., increase acceleration and/or velocity) of the substrate transport apparatus 550 to substantially avoid or otherwise mitigate a decrease in wafer productivity.

In some aspects, the modular metrology station 400D provides for the recordation and establishment of trends with respect to wafer aligner 553 wafer offsets and wafer fiducial locations. For example, as may be realized, given the repetitiveness of operations in the substrate processing apparatus 555, the aligner 553 may determine typical offsets and fiducial locations of the wafers S aligned thereby and convey that information to the controller 11091 and/or modular metrology station 400D. The typical offset and fiducial location information may be employed by the controller 11091 and/or the modular metrology station 400D (such as where computational ability is offloaded from the controller 11091 to the modular metrology station 400D) to predict wafer offsets before placing a wafer on the aligner 553. Here, the aligner 553 may be employed to scan wafer offsets within tighter ranges (smaller magnitudes) to improve the accuracy of the aligner 553.

As described herein, the modular metrology station 400C includes sensors 500G-500I disposed on a process chamber lid 552. The sensors 500G-500I may include temperature sensors disposed to monitor the wafer S temperature (and/or arm link temperatures as described herein) before and after the wafer S is processed within the respective substrate processing module 11030. As may be realized, the wafer S temperature may impact the acceleration limit of the substrate transport apparatus 550 end effector EE before wafer slippage occurs. Here, the motion of the substrate transport apparatus 550 may be optimized by the controller 11091 (or by the modular metrology station 400B where such optimization is conveyed to the controller 11091) so that wafer S transfer is effected at a maximum acceleration based on the wafer S temperature reported at a start of the wafer S transfer motion.

The modular metrology station 400C and the monitoring of the wafer S temperatures may effect an adaptive substrate transport apparatus 550 operation to increase a life of the substrate transport apparatus. For example, where data obtained by the modular metrology station 400C indicates an upward trend in a wafer S temperature from a substrate processing module 11030 pick operation, such wafer S temperature information may be conveyed from the modular metrology station 400C to the controller 11091 so that the controller 11091 may adaptively change the motion of the substrate transport apparatus 550 so that the motion (e.g., acceleration and/or velocity) is reduced and/or a robot idle time is increased to allow for bearings (and other components of the substrate transport apparatus 550) affected by the increased wafer/process module temperatures to cool down.

Still referring to FIG. 5, in one or more aspects, a lid of a transfer chamber (such as transfer chamber 11025) in which the substrate transport apparatus 550 is located includes sensors 500K associated with a modular metrology station in a manner substantially similar to process chamber lid 552 described herein. Here, the sensors 500K of the modular metrology station include suitable temperature sensors (e.g., infrared or other suitable sensors) disposed to sense a temperature of a flange 550F (e.g., the mechanical interface between the drive 299 and the chamber in which the substrate transport apparatus is disposed) and/or arm links (see FIGS. 2E-2I) of the substrate transport apparatus 550. The temperature of the flange 550F and the arm links provides for the controller 11091 to effect wafer S placement accounting for thermal effects on the substrate transport apparatus 550. For example, the controller 11091 may adapt the servo loop control parameters of the substrate transport apparatus to prevent instability caused by changes in temperature. The lid of the transfer chamber 11025 may also include optical/vision sensors (e.g., cameras) so that the modular metrology station thereof is configured to optically track a positon (and or thermal growth/shrinkage) of the substrate transport apparatus 550. Here, placement accuracy can be improved where the controller 11091 employs the temperature and/or position feedback of the different links to estimate thermal expansion of the arm links to correct kinematic models of the substrate transport apparatus to place the wafer at the target destination accounting for thermal effects on the arm links.

Referring to FIGS. 1A and 5, air flow from the fan filter unit FFU of the mini-environment (or front end unit) 11060 may be monitored by a flow meter/sensor 500L of a modular metrology station 400E. The air flow may be a variable of the substrate processing apparatus 11090, 555 that may affect operation of the substrate transport apparatus 11013 within the mini-environment 11060 (e.g., where the substrate transport apparatus 11013 may be substantially similar to substrate transport apparatus 550). For example, the air flow (e.g., volume, velocity, etc.) may affect the wafer placement repeatability of the substrate transport apparatus 11013 (e.g., affecting settling times, inducing vibrations in the arm 550A, etc.) where the controller 11061 may dynamically adapt/adjust the motion of the substrate transport apparatus 11013 to minimize the effects of the fan filter unit FFU air flow.

Referring to table 3 below, additional substrate transport apparatus variables or predetermined functional characteristics may be employed as predetermined characteristics or metrics of the wafer motion quality index WMQIdx. The additional variables described in Table 3 are described in association with substrate transport apparatus performance within, for example, a template move. Suitable examples of template moves can be found in, for example, U.S. patent application Ser. No. 15/971,827 filed on May 4, 2018 and titled “Method and Apparatus for Health Assessment of Transport Apparatus”, the disclosure of which is incorporated herein by reference in its entirety.

TABLE 3
Robot Performance Variables

| Robot Component | Robot Level Variable per Template Move |
|---|---|
| Motor | Peak Temperature; |
| | Peak current; |
| | Peak voltage; |
| | Mechanical work; |
| End-Effector | Peak Tracking Errors; |
| | Peak Acceleration Overshoots; |
| | Root-Mean-Square acceleration; |
| Dynamic Model | Peak dynamic model error; |

A transport apparatus performance index RPIdx may be defined in terms of the variables described in Table 3 where the transport apparatus performance index RPIdx is defined as:

$$RPIdx = \frac{1}{\begin{matrix}( PMTIdx ) ( PMCIdx ) ( PMVIdx ) ( MMWIdx ) \\ ( PTEIdx ) ( PAOIdx ) ( RMSAIdx ) ( PDMEIdx )\end{matrix}} \qquad [ eq . 11 ]$$

where, PMTIdx is a peak motor temperature index, PMCIdx is a peak motor current index, PMVIdx is a peak motor voltage index, MMWIdx is a peak motor mechanical work index, PTEIdx is a peak tracking error index, PAOIdx is a peak acceleration overshoot index, RMSIdx is a root-mean-square acceleration index, and PDMEIdx is a peak dynamic model error index. In a manner similar to that described above with respect to the definitions presented in equations [2] to [10], each index of equation may be defined as the ratio of the most recent value of the respective variable in Table 3 over its allowable threshold. The system substrate transport apparatus performance index RPIdx may be added to the numerator of equation [1] so that the wafer motion quality index WMQIdx is further defined as:

$$WHQIdx = \frac{( WPHIdx ) ( GMIdx ) ( PMIdx ) ( WMVIdx ) ( RPIdx )}{( WHEIdx ) ( WSIdx ) ( STIdx ) ( WHVIdx ) ( WWEIdx )} \qquad [ eq . 12 ]$$

Referring again to FIG. 5, the aspects of the disclosed embodiment provide for a scalable platform for robotic control and diagnostics as described herein. The modular metrology stations 400 may be added to process equipment (such as process modules 598, substrate transport apparatus 599, and any other suitable process equipment (such as described herein) that is added to an existing substrate processing apparatus 555. For example, FIGS. 1C, 1D, and 2A-2D illustrate scalable linear and cluster tool configurations in which the modular metrology stations 400 may be employed to provide adaptive operation of tool components 800 (FIG. 8) as well as system level component diagnostics (as described herein). As described herein, the additional modular metrology stations 400 may be coupled to the controller 11091 in any suitable manner (such as plug-and-play) to effect a modular addition of the modular metrology station 400 and the substrate processing equipment associated therewith.

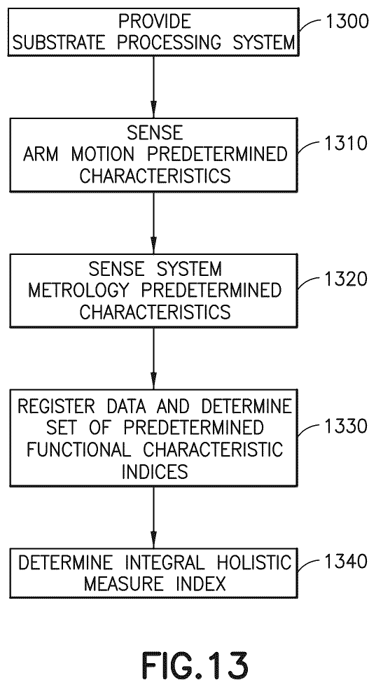

Referring to FIGS. 5 and 13 an exemplary method will be described in accordance with aspects of the disclosed embodiment. The method includes providing a substrate processing system 555 (such as those described herein) (FIG. 13, Block 1300). At least one arm motion sensor (also referred to as transport echelon sensors) 566, coupled to the controller 11091, senses arm motion (or transport echelon) predetermined characteristics (FIG. 13, Block 1310). At least one system metrology sensor (also referred to as process echelon metrology sensors) 500A-500z, coupled to the controller 11091, sense system metrology (or process echelon) predetermined characteristics, different that the arm motion predetermined characteristics (FIG. 13, Block 1320). The controller 11091 registers data DAT, DAT2 from at least one of the at least one arm motion sensor 566 and the at least one system metrology sensor 500A-500z, and determines from the registered data DAT, DAT2 a set of predetermined functional characteristic indices (as described herein) (FIG. 13, Block 1330). Each predetermined functional index corresponds to a different respective predetermined functional characteristic, of arm motion transporting the substrate S or of the substrate processing system 555, and informs a relationship between the respective predetermined functional characteristic and a motion quality of the substrate S transported by the movable arm 550A. The integral holistic measure index (e.g., wafer motion quality index WMQIdx) of holistic motion quality of the substrate S transported by the movable arm 550A is determined (FIG. 13, Block 1340) by the controller 11091 from the set of predetermined functional characteristic indices.

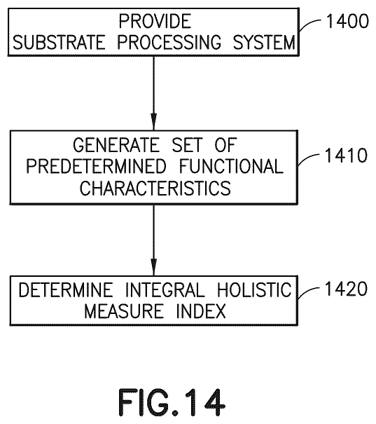

Referring to FIGS. 5 and 14, an exemplary method will be described in accordance with aspects of the disclosed embodiment. The method includes providing a substrate processing system 555 (such as those described herein) (FIG. 14, Block 1400). A set of predetermined functional characteristic indices are generated (FIG. 14, Block 1410) with the controller 11091 from sensor data DAT, DAT2 embodying both the transport echelon (e.g., arm motion) predetermined characteristics, and the process echelon (or system) metrology predetermined characteristics. As described above, each predetermined functional characteristic index corresponds to a different respective predetermined functional characteristic, of the substrate transport apparatus 550 transporting the substrate S or of the substrate processing echelon, and informs a relationship between the respective predetermined functional characteristic and a motion quality of the substrate S transported by the substrate transport apparatus 550. The integral holistic measure index (e.g., wafer motion quality index WMQIdx) of holistic motion quality of the substrate S transported by the substrate transport apparatus 550 is determined (FIG. 14, Block 1420) with the controller from the set of predetermined functional characteristic indices.

In accordance with one or more aspects of the disclosed embodiment a substrate processing system comprises:
a frame forming a substrate transport space within the substrate processing system;
a substrate transport apparatus operably coupled to the frame with a movable arm and a drive section configured to move the movable arm and transport a substrate, held on an end effector of the arm, through the transport space from a first position of the substrate processing system to a second position of the substrate processing system different than the first position; and
a controller operably coupled to the movable arm and drive section so as to effect movement of the movable arm to the different system positions, the controller is communicably coupled to at least one arm motion sensor and at least one system metrology sensor, the at least one arm motion sensor senses arm motion predetermined characteristics, and the at least one system metrology sensor senses system metrology predetermined characteristics, different that the arm motion predetermined characteristics;
wherein the controller is configured to register data, from at least one of the at least one arm motion sensor and the at least one system metrology sensor, and determine from the registered data a set of predetermined functional characteristic indices, each index corresponding to a different respective predetermined functional characteristic, of arm motion transporting the substrate or of the substrate processing system, and informing a relationship between the respective predetermined functional characteristic and a motion quality of the substrate transported by the movable arm; and
the controller is configured to determine from the set of predetermined functional characteristic indices an integral holistic measure index of holistic motion quality of the substrate transported by the movable arm.

In accordance with one or more aspects of the disclosed embodiment the respective predetermined functional characteristic includes at least one of a substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

In accordance with one or more aspects of the disclosed embodiment the respective predetermined functional characteristic includes at least one of substrates processed per hour and Wafer Slippage.

In accordance with one or more aspects of the disclosed embodiment the set of predetermined functional characteristic indices includes an index for at least one of the respective predetermined functional characteristic that includes at least one of substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

In accordance with one or more aspects of the disclosed embodiment the set of predetermined functional characteristic indices includes an index for at least one of the respective predetermined functional characteristic that includes at least one of substrates processed per hour and Wafer Slippage.

In accordance with one or more aspects of the disclosed embodiment at least one of the system metrology predetermined characteristics is derivative of arm motion.

In accordance with one or more aspects of the disclosed embodiment the controller is configured to determine from the registered data an operative value for each different respective predetermined functional characteristic and factor the operative value with respect to a corresponding reference value for each different predetermined functional characteristic.

In accordance with one or more aspects of the disclosed embodiment each different predetermined functional characteristic is dependent on at least one unique control parameter of the arm, or the system, controlled by controller commands.

In accordance with one or more aspects of the disclosed embodiment the controller monitors the holistic measure index, identifies trends therein, and adaptively generates commands that effect changes to the control parameter varying the dependent predetermined functional characteristic and its corresponding index in response to the identified trends.

In accordance with one or more aspects of the disclosed embodiment the controller monitors changes in the holistic measure index from transients in at least one index of a respective predetermined functional characteristic responsive to controller commands changing a control parameter determinative of the respective predetermined functional characteristic.

In accordance with one or more aspects of the disclosed embodiment the controller monitors changes in the holistic measure index from transients in at least one index of a respective predetermined functional characteristic and in response to a predetermined adverse change of the holistic measure index commands a change in a control parameter determinative of another respective predetermined functional characteristic that offsets, at least in part, the predetermined adverse change of the holistic measure index.

In accordance with one or more aspects of the disclosed embodiment the controller is configured to compare the change in the holistic measure index from the transients in the at least one predetermined functional characteristic index relative to another change in the holistic measure index from other different transients in at least another different predetermined functional characteristic index, and from the comparison of relative changes in holistic measure index by the transients and by the other different transients, scale the at least one predetermined functional characteristic index and the at least another different predetermined functional characteristic index relative to each other.

In accordance with one or more aspects of the disclosed embodiment the controller is programmed with an adaptive control and/or machine learning-based law that commands changes in control parameters so as to generate a maximum holistic measure index, or minimize progression of adverse changes of the holistic measure index.

In accordance with one or more aspects of the disclosed embodiment at least one of the predetermined functional characteristics is a system functional characteristic including at least one of a load lock pump and vent time, load lock vertical lift motion time, load lock vibration signature, slot valve time interval between opening and closing, slot valve time interval between subsequent openings, time slot valve opening and closing time stamp, slot valve vibration signature, substrate aligner align time, historical substrate offsets and fiducial locations, substrate temperature, movable arm temperatures, substrate transport apparatus flange temperature, vacuum level, and air flow.

In accordance with one or more aspects of the disclosed embodiment at least one of the predetermined functional characteristics is an arm mechanism functional characteristic including at least one of a motor temperature, motor current, motor voltage, motor mechanical work, end effector tracking error, end effector acceleration overshoot, end effector root-mean-square acceleration, and dynamic model error.

In accordance with one or more aspects of the disclosed embodiment the at least one arm motion sensor, and the at least one system metrology sensor is a modular metrology sensor having a common modular platform that is selectably configurable.

In accordance with one or more aspects of the disclosed embodiment a substrate processing system comprises:
a frame;
a substrate processing station and at least one substrate input or output station connected to the frame and forming a substrate process echelon of the substrate processing system;
a substrate transport movably mounted to the frame and configured to transport substrates along the substrate processing echelon between the input or output station and substrate processing station, the substrate transport forming a transport echelon of the substrate processing system;
a suite of sensors including, transport echelon sensors communicably coupled to the substrate transport disposed to sense transport echelon predetermined characteristics, and process echelon metrology sensors disposed to sense process echelon metrology predetermined characteristics, different than the transport echelon predetermined characteristics; and
a controller communicably coupled to the transport echelon sensors and the metrology echelon sensors, and configured to generate, from sensor data embodying both the transport echelon predetermined characteristics, and the process echelon metrology predetermined characteristics, a set of predetermined functional characteristic indices, each index corresponding to a different respective predetermined functional characteristic, of the substrate transport transporting the substrate or of the substrate processing echelon, and informing a relationship between the respective predetermined functional characteristic and a motion quality of the substrate transported by the substrate transport; and
the controller is configured to determine from the set of predetermined functional characteristic indices an integral holistic measure index of holistic motion quality of the substrate transported by the substrate transport.

In accordance with one or more aspects of the disclosed embodiment the substrate transport includes a transport arm and a drive section configured to move the transport arm and transport the substrate held on an end effector of the transport arm.

In accordance with one or more aspects of the disclosed embodiment the respective predetermined functional characteristic includes at least one of a substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

In accordance with one or more aspects of the disclosed embodiment the respective predetermined functional characteristic includes at least one of substrates processed per hour and Wafer Slippage.

In accordance with one or more aspects of the disclosed embodiment the set of predetermined functional characteristic indices includes an index for at least one of the respective predetermined functional characteristic that includes at least one of substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

In accordance with one or more aspects of the disclosed embodiment the set of predetermined functional characteristic indices includes an index for at least one of the respective predetermined functional characteristic that includes at least one of substrates processed per hour and Wafer Slippage.

In accordance with one or more aspects of the disclosed embodiment at least one of the process echelon metrology predetermined characteristics is derivative of substrate transport arm motion.

In accordance with one or more aspects of the disclosed embodiment the controller is configured to:
register data, from at least one of the transport echelon sensors and the process echelon metrology sensor; and
determine from the registered data an operative value for each different respective predetermined functional characteristic and factor the operative value with respect to a corresponding reference value for each different predetermined functional characteristic.

In accordance with one or more aspects of the disclosed embodiment each different predetermined functional characteristic is dependent on at least one unique control parameter of the substrate transport, or the substrate processing system, controlled by controller commands.

In accordance with one or more aspects of the disclosed embodiment the controller monitors the holistic measure index, identifies trends therein, and adaptively generates commands that effect changes to the control parameter varying the dependent predetermined functional characteristic and its corresponding index in response to the identified trends.

In accordance with one or more aspects of the disclosed embodiment the controller monitors changes in the holistic measure index from transients in at least one index of a respective predetermined functional characteristic responsive to controller commands changing a control parameter determinative of the respective predetermined functional characteristic.

In accordance with one or more aspects of the disclosed embodiment the controller monitors changes in the holistic measure index from transients in at least one index of a respective predetermined functional characteristic and in response to a predetermined adverse change of the holistic measure index commands a change in a control parameter determinative of another respective predetermined functional characteristic that offsets, at least in part, the predetermined adverse change of the holistic measure index.

In accordance with one or more aspects of the disclosed embodiment the controller is configured to compare the change in the holistic measure index from the transients in the at least one predetermined functional characteristic index relative to another change in the holistic measure index from other different transients in at least another different predetermined functional characteristic index, and from the comparison of relative changes in holistic measure index by the transients and by the other different transients, scale the at least one predetermined functional characteristic index and the at least another different predetermined functional characteristic index relative to each other.

In accordance with one or more aspects of the disclosed embodiment the controller is programmed with an adaptive control and/or machine learning-based law that commands changes in control parameters so as to generate a maximum holistic measure index, or minimize progression of adverse changes of the holistic measure index.

In accordance with one or more aspects of the disclosed embodiment at least one of the predetermined functional characteristics is a system functional characteristic including at least one of a load lock pump and vent time, load lock vertical lift motion time, load lock vibration signature, slot valve time interval between opening and closing, slot valve time interval between subsequent openings, time slot valve opening and closing time stamp, slot valve vibration signature, substrate aligner align time, historical substrate offsets and fiducial locations, substrate temperature, movable arm temperatures, substrate transport apparatus flange temperature, vacuum level, and air flow.

In accordance with one or more aspects of the disclosed embodiment at least one of the predetermined functional characteristics is an arm mechanism functional characteristic including at least one of a motor temperature, motor current, motor voltage, motor mechanical work, end effector tracking error, end effector acceleration overshoot, end effector root-mean-square acceleration, and dynamic model error.

In accordance with one or more aspects of the disclosed embodiment the transport echelon sensors, and the metrology echelon sensors are modular metrology sensors having respective common modular platforms that are selectably configurable.

In accordance with one or more aspects of the disclosed embodiment a method comprises:
providing a substrate processing system having:
a frame forming a substrate transport space within the substrate processing system
a substrate transport apparatus operably coupled to the frame with a movable arm and a drive section configured to move the movable arm and transport a substrate, held on an end effector of the arm, through the transport space from a first position of the substrate processing system to a second position of the substrate processing system different than the first position, and
a controller operably coupled to the movable arm and drive section so as to effect movement of the movable arm to the different system positions;
sensing with at least one arm motion sensor, coupled to the controller, arm motion predetermined characteristics;
sensing with at least one system metrology sensor, coupled to the controller, system metrology predetermined characteristics, different that the arm motion predetermined characteristics;
registering data, with the controller, from at least one of the at least one arm motion sensor and the at least one system metrology sensor, and determining from the registered data a set of predetermined functional characteristic indices, each index corresponding to a different respective predetermined functional characteristic, of arm motion transporting the substrate or of the substrate processing system, and informing a relationship between the respective predetermined functional characteristic and a motion quality of the substrate transported by the movable arm; and
determining, with the controller, from the set of predetermined functional characteristic indices an integral holistic measure index of holistic motion quality of the substrate transported by the movable arm.

In accordance with one or more aspects of the disclosed embodiment the respective predetermined functional characteristic includes at least one of a substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

In accordance with one or more aspects of the disclosed embodiment the respective predetermined functional characteristic includes at least one of substrates processed per hour and Wafer Slippage.

In accordance with one or more aspects of the disclosed embodiment the set of predetermined functional characteristic indices includes an index for at least one of the respective predetermined functional characteristic that includes at least one of substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

In accordance with one or more aspects of the disclosed embodiment the set of predetermined functional characteristic indices includes an index for at least one of the respective predetermined functional characteristic that includes at least one of substrates processed per hour and Wafer Slippage.

In accordance with one or more aspects of the disclosed embodiment at least one of the system metrology predetermined characteristics is derivative of arm motion.

In accordance with one or more aspects of the disclosed embodiment the method further comprises, with the controller, determining from the registered data an operative value for each different respective predetermined functional characteristic and factor the operative value with respect to a corresponding reference value for each different predetermined functional characteristic.

In accordance with one or more aspects of the disclosed embodiment each different predetermined functional characteristic is dependent on at least one unique control parameter of the arm, or the system, controlled by controller commands.

In accordance with one or more aspects of the disclosed embodiment the method further comprises, with the controller, monitoring the holistic measure index, identifying trends therein, and adaptively generating commands that effect changes to the control parameter varying the dependent predetermined functional characteristic and its corresponding index in response to the identified trends.

In accordance with one or more aspects of the disclosed embodiment the method further comprises, with the controller, monitoring changes in the holistic measure index from transients in at least one index of a respective predetermined functional characteristic responsive to controller commands changing a control parameter determinative of the respective predetermined functional characteristic.

In accordance with one or more aspects of the disclosed embodiment the method further comprises, with the controller, monitoring changes in the holistic measure index from transients in at least one index of a respective predetermined functional characteristic and in response to a predetermined adverse change of the holistic measure index commanding a change in a control parameter determinative of another respective predetermined functional characteristic that offsets, at least in part, the predetermined adverse change of the holistic measure index.

In accordance with one or more aspects of the disclosed embodiment the method further comprises, with the controller, comparing the change in the holistic measure index from the transients in the at least one predetermined functional characteristic index relative to another change in the holistic measure index from other different transients in at least another different predetermined functional characteristic index, and from the comparison of relative changes in holistic measure index by the transients and by the other different transients, scaling the at least one predetermined functional characteristic index and the at least another different predetermined functional characteristic index relative to each other.

In accordance with one or more aspects of the disclosed embodiment the controller is programmed with an adaptive control and/or machine learning-based law that commands changes in control parameters so as to generate a maximum holistic measure index, or minimize progression of adverse changes of the holistic measure index.

In accordance with one or more aspects of the disclosed embodiment at least one of the predetermined functional characteristics is a system functional characteristic including at least one of a load lock pump and vent time, load lock vertical lift motion time, load lock vibration signature, slot valve time interval between opening and closing, slot valve time interval between subsequent openings, time slot valve opening and closing time stamp, slot valve vibration signature, substrate aligner align time, historical substrate offsets and fiducial locations, substrate temperature, movable arm temperatures, substrate transport apparatus flange temperature, vacuum level, and air flow.

In accordance with one or more aspects of the disclosed embodiment at least one of the predetermined functional characteristics is an arm mechanism functional characteristic including at least one of a motor temperature, motor current, motor voltage, motor mechanical work, end effector tracking error, end effector acceleration overshoot, end effector root-mean-square acceleration, and dynamic model error.

In accordance with one or more aspects of the disclosed embodiment the at least one arm motion sensor, and the at least one system metrology sensor is a modular metrology sensor having a common modular platform that is selectably configurable.

In accordance with one or more aspects of the disclosed embodiment a method comprises:
providing a substrate processing system having:
a frame,
a substrate processing station and at least one substrate input or output station connected to the frame and forming a substrate process echelon of the substrate processing system,
a substrate transport movably mounted to the frame and configured to transport substrates along the substrate processing echelon between the input or output station and substrate processing station, the substrate transport forming a transport echelon of the substrate processing system,
a suite of sensors including, transport echelon sensors communicably coupled to the substrate transport disposed to sense transport echelon predetermined characteristics, and process echelon metrology sensors disposed to sense process echelon metrology predetermined characteristics, different than the transport echelon predetermined characteristics, and
a controller communicably coupled to the transport echelon sensors and the metrology echelon sensors;
generating with the controller, from sensor data embodying both the transport echelon predetermined characteristics, and the process echelon metrology predetermined characteristics, a set of predetermined functional characteristic indices, each index corresponding to a different respective predetermined functional characteristic, of the substrate transport transporting the substrate or of the substrate processing echelon, and informing a relationship between the respective predetermined functional characteristic and a motion quality of the substrate transported by the substrate transport; and
determining, with the controller, from the set of predetermined functional characteristic indices an integral holistic measure index of holistic motion quality of the substrate transported by the substrate transport.

In accordance with one or more aspects of the disclosed embodiment the substrate transport includes a transport arm and a drive section configured to move the transport arm and transport the substrate held on an end effector of the transport arm.

In accordance with one or more aspects of the disclosed embodiment the respective predetermined functional characteristic includes at least one of a substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

In accordance with one or more aspects of the disclosed embodiment the respective predetermined functional characteristic includes at least one of substrates processed per hour and Wafer Slippage.

In accordance with one or more aspects of the disclosed embodiment the set of predetermined functional characteristic indices includes an index for at least one of the respective predetermined functional characteristic that includes at least one of substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

In accordance with one or more aspects of the disclosed embodiment the set of predetermined functional characteristic indices includes an index for at least one of the respective predetermined functional characteristic that includes at least one of substrates processed per hour and Wafer Slippage.

In accordance with one or more aspects of the disclosed embodiment at least one of the process echelon metrology predetermined characteristics is derivative of substrate transport arm motion.

In accordance with one or more aspects of the disclosed embodiment method further comprises, with the controller:
registering data, from at least one of the transport echelon sensors and the process echelon metrology sensor; and
determining from the registered data an operative value for each different respective predetermined functional characteristic and factor the operative value with respect to a corresponding reference value for each different predetermined functional characteristic.

In accordance with one or more aspects of the disclosed embodiment each different predetermined functional characteristic is dependent on at least one unique control parameter of the substrate transport, or the substrate processing system, controlled by controller commands.

In accordance with one or more aspects of the disclosed embodiment method further comprises, with the controller, monitoring the holistic measure index, identifying trends therein, and adaptively generating commands that effect changes to the control parameter varying the dependent predetermined functional characteristic and its corresponding index in response to the identified trends.

In accordance with one or more aspects of the disclosed embodiment method further comprises, with the controller, monitoring changes in the holistic measure index from transients in at least one index of a respective predetermined functional characteristic responsive to controller commands changing a control parameter determinative of the respective predetermined functional characteristic.

In accordance with one or more aspects of the disclosed embodiment method further comprises, with the controller, monitoring changes in the holistic measure index from transients in at least one index of a respective predetermined functional characteristic and in response to a predetermined adverse change of the holistic measure index commanding a change in a control parameter determinative of another respective predetermined functional characteristic that offsets, at least in part, the predetermined adverse change of the holistic measure index.

In accordance with one or more aspects of the disclosed embodiment method further comprises, with the controller, comparing the change in the holistic measure index from the transients in the at least one predetermined functional characteristic index relative to another change in the holistic measure index from other different transients in at least another different predetermined functional characteristic index, and from the comparison of relative changes in holistic measure index by the transients and by the other different transients, scaling the at least one predetermined functional characteristic index and the at least another different predetermined functional characteristic index relative to each other.

In accordance with one or more aspects of the disclosed embodiment the controller is programmed with an adaptive control law that commands changes in control parameters so as to generate a maximum holistic measure index, or minimize progression of adverse changes of the holistic measure index.

In accordance with one or more aspects of the disclosed embodiment at least one of the predetermined functional characteristics is a system functional characteristic including at least one of a load lock pump and vent time, load lock vertical lift motion time, load lock vibration signature, slot valve time interval between opening and closing, slot valve time interval between subsequent openings, time slot valve opening and closing time stamp, slot valve vibration signature, substrate aligner align time, historical substrate offsets and fiducial locations, substrate temperature, movable arm temperatures, substrate transport apparatus flange temperature, vacuum level, and air flow.

In accordance with one or more aspects of the disclosed embodiment at least one of the predetermined functional characteristics is an arm mechanism functional characteristic including at least one of a motor temperature, motor current, motor voltage, motor mechanical work, end effector tracking error, end effector acceleration overshoot, end effector root-mean-square acceleration, and dynamic model error.

In accordance with one or more aspects of the disclosed embodiment the transport echelon sensors, and the metrology echelon sensors are modular metrology sensors having respective common modular platforms that are selectably configurable.

It should be understood that the foregoing description is only illustrative of the aspects of the disclosed embodiment. Various alternatives and modifications can be devised by those skilled in the art without departing from the aspects of the disclosed embodiment. Accordingly, the aspects of the disclosed embodiment are intended to embrace all such alternatives, modifications and variances that fall within the scope of any claims appended hereto. Further, the mere fact that different features are recited in mutually different dependent or independent claims does not indicate that a combination of these features cannot be advantageously used, such a combination remaining within the scope of the aspects of the disclosed embodiment.

What is claimed is:

1. A substrate processing system comprising:
a frame forming a substrate transport space within the substrate processing system;
a substrate transport apparatus operably coupled to the frame with a movable arm and a drive section configured to move the movable arm and transport a substrate, held on an end effector of the arm, through the transport space from a first position of the substrate processing system to a second position of the substrate processing system different than the first position; and
a controller operably coupled to the movable arm and drive section so as to effect movement of the movable arm to the different system positions, the controller is communicably coupled to at least one arm motion sensor and at least one system metrology sensor, the at least one arm motion sensor senses arm motion predetermined characteristics, and the at least one system metrology sensor senses system metrology predetermined characteristics, different that the arm motion predetermined characteristics;
wherein the controller is configured to register data, from at least one of the at least one arm motion sensor and the at least one system metrology sensor, and determine from the registered data a set of predetermined functional characteristic indices, each index corresponding to a different respective predetermined functional characteristic, of arm motion transporting the substrate or of the substrate processing system, and informing a relationship between the respective predetermined functional characteristic and a motion quality of the substrate transported by the movable arm; and
the controller is configured to determine from the set of predetermined functional characteristic indices an integral holistic measure index of holistic motion quality of the substrate transported by the movable arm.

2. The substrate processing system of claim 1, wherein the respective predetermined functional characteristic includes at least one of a substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

3. The substrate processing system of claim 1, wherein the set of predetermined functional characteristic indices includes an index for at least one of the respective predetermined functional characteristic that includes at least one of substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

4. The substrate processing system of claim 1, wherein at least one of the system metrology predetermined characteristics is derivative of arm motion.

5. The substrate processing system of claim 1, wherein the controller is configured to determine from the registered data an operative value for each different respective predetermined functional characteristic and factor the operative value with respect to a corresponding reference value for each different predetermined functional characteristic.

6. The substrate processing system of claim 1, wherein the controller monitors:
the holistic measure index, identifies trends therein, and adaptively generates commands that effect changes to the control parameter varying the dependent predetermined functional characteristic and its corresponding index in response to the identified trends;
changes in the holistic measure index from transients in at least one index of a respective predetermined functional characteristic responsive to controller commands changing a control parameter determinative of the respective predetermined functional characteristic;
changes in the holistic measure index from transients in at least one index of a respective predetermined functional characteristic and in response to a predetermined adverse change of the holistic measure index commands a change in a control parameter determinative of another respective predetermined functional characteristic that offsets, at least in part, the predetermined adverse change of the holistic measure index.

7. The substrate processing system of claim 1, wherein the controller is programmed with one or more of an adaptive control law and a machine learning-based law that commands changes in control parameters so as to generate a maximum holistic measure index, or minimize progression of adverse changes of the holistic measure index.

8. The substrate processing system of claim 1, wherein at least one of the predetermined functional characteristics is:
a system functional characteristic including at least one of a load lock pump and vent time, load lock vertical lift motion time, load lock vibration signature, slot valve time interval between opening and closing, slot valve time interval between subsequent openings, time slot valve opening and closing time stamp, slot valve vibration signature, substrate aligner align time, historical substrate offsets and fiducial locations, substrate temperature, movable arm temperatures, substrate transport apparatus flange temperature, vacuum level, and air flow; or
an arm mechanism functional characteristic including at least one of a motor temperature, motor current, motor voltage, motor mechanical work, end effector tracking error, end effector acceleration overshoot, end effector root-mean-square acceleration, and dynamic model error.

9. A substrate processing system comprising:
a frame;
a substrate processing station and at least one substrate input or output station connected to the frame and forming a substrate process echelon of the substrate processing system;
a substrate transport movably mounted to the frame and configured to transport substrates along the substrate processing echelon between the input or output station and substrate processing station, the substrate transport forming a transport echelon of the substrate processing system;
a suite of sensors including, transport echelon sensors communicably coupled to the substrate transport disposed to sense transport echelon predetermined characteristics, and process echelon metrology sensors disposed to sense process echelon metrology predetermined characteristics, different than the transport echelon predetermined characteristics; and
a controller communicably coupled to the transport echelon sensors and the metrology echelon sensors, and configured to generate, from sensor data embodying both the transport echelon predetermined characteristics, and the process echelon metrology predetermined characteristics, a set of predetermined functional characteristic indices, each index corresponding to a different respective predetermined functional characteristic, of the substrate transport transporting the substrate or of the substrate processing echelon, and informing a relationship between the respective predetermined functional characteristic and a motion quality of the substrate transported by the substrate transport; and
the controller is configured to determine from the set of predetermined functional characteristic indices an integral holistic measure index of holistic motion quality of the substrate transported by the substrate transport.

10. The substrate processing system of claim 9, wherein the respective predetermined functional characteristic includes at least one of a substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

11. The substrate processing system of claim 9, wherein the set of predetermined functional characteristic indices includes an index for at least one of the respective predetermined functional characteristic that includes at least one of substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

12. The substrate processing system of claim 9, wherein at least one of the process echelon metrology predetermined characteristics is derivative of substrate transport arm motion.

13. The substrate processing system of claim 9, wherein the controller is configured to:
register data, from at least one of the transport echelon sensors and the process echelon metrology sensor; and
determine from the registered data an operative value for each different respective predetermined functional characteristic and factor the operative value with respect to a corresponding reference value for each different predetermined functional characteristic.

14. The substrate processing system of claim 9, wherein the controller monitors:
the holistic measure index, identifies trends therein, and adaptively generates commands that effect changes to the control parameter varying the dependent predetermined functional characteristic and its corresponding index in response to the identified trends;
changes in the transient measure index from transients in at least one index of a respective predetermined functional characteristic responsive to controller commands changing a control parameter determinative of the respective predetermined functional characteristic; or
changes in the holistic measure index from transients in at least one index of a respective predetermined functional characteristic and in response to a predetermined adverse change of the holistic measure index commands a change in a control parameter determinative of another respective predetermined functional characteristic that offsets, at least in part, the predetermined adverse change of the holistic measure index.

15. The substrate processing system of claim 9, wherein the controller is programmed with one or more of an adaptive control law and a machine learning-based law that commands changes in control parameters so as to generate a maximum holistic measure index, or minimize progression of adverse changes of the holistic measure index.

16. The substrate processing system of claim 9, wherein at least one of the predetermined functional characteristics is:
a system functional characteristic including at least one of a load lock pump and vent time, load lock vertical lift motion time, load lock vibration signature, slot valve time interval between opening and closing, slot valve time interval between subsequent openings, time slot valve opening and closing time stamp, slot valve vibration signature, substrate aligner align time, historical substrate offsets and fiducial locations, substrate temperature, movable arm temperatures, substrate transport apparatus flange temperature, vacuum level, and air flow; or
an arm mechanism functional characteristic including at least one of a motor temperature, motor current, motor voltage, motor mechanical work, end effector tracking error, end effector acceleration overshoot, end effector root-mean-square acceleration, and dynamic model error.

17. A method comprising:
providing a substrate processing system having:
a frame forming a substrate transport space within the substrate processing system
a substrate transport apparatus operably coupled to the frame with a movable arm and a drive section configured to move the movable arm and transport a substrate, held on an end effector of the arm, through the transport space from a first position of the substrate processing system to a second position of the substrate processing system different than the first position, and
a controller operably coupled to the movable arm and drive section so as to effect movement of the movable arm to the different system positions;
sensing with at least one arm motion sensor, coupled to the controller, arm motion predetermined characteristics;
sensing with at least one system metrology sensor, coupled to the controller, system metrology predetermined characteristics, different that the arm motion predetermined characteristics;
registering data, with the controller, from at least one of the at least one arm motion sensor and the at least one system metrology sensor, and determining from the registered data a set of predetermined functional characteristic indices, each index corresponding to a different respective predetermined functional characteristic, of arm motion transporting the substrate or of the substrate processing system, and informing a relationship between the respective predetermined functional characteristic and a motion quality of the substrate transported by the movable arm; and
determining, with the controller, from the set of predetermined functional characteristic indices an integral holistic measure index of holistic motion quality of the substrate transported by the movable arm.

18. The method of claim 17, wherein the respective predetermined functional characteristic includes at least one of a substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

19. The method of claim 17, wherein the set of predetermined functional characteristic indices includes an index for at least one of the respective predetermined functional characteristic that includes at least one of substrates processed per hour, position loop servos Gain Margin, position loop servos Phase Margin, Wafer Handling Error, Wafer Slippage, Settling Time, Wafer Handoff Vibration, Wafer Motion Wobble, and Wafer Motion Vibration.

20. The method of claim 17, further comprising, with the controller, monitoring:
the holistic measure index, identifying trends therein, and adaptively generating commands that effect changes to the control parameter varying the dependent predetermined functional characteristic and its corresponding index in response to the identified trends;
changes in the holistic measure index from transients in at least one index of a respective predetermined functional characteristic responsive to controller commands changing a control parameter determinative of the respective predetermined functional characteristic; or
changes in the holistic measure index from transients in at least one index of a respective predetermined functional characteristic and in response to a predetermined adverse change of the holistic measure index commanding a change in a control parameter determinative of another respective predetermined functional characteristic that offsets, at least in part, the predetermined adverse change of the holistic measure index.
